(19) United States
(12) Patent Application Publication
(10) Pub. No.: US 2026/0179521 A1
(43) Pub. Date: Jun. 25, 2026

(54) DISPLAY PANEL AND DISPLAY DEVICE INCLUDING THE SAME

(71) Applicant: LG DISPLAY CO., LTD., Seoul (KR)

(72) Inventors: Byungsam Min, Goyang-si (KR); Chaiwon Kim, Seongnam-si (KR)

(73) Assignee: LG DISPLAY CO., LTD., Seoul (KR)

(21) Appl. No.: 19/402,049

(22) Filed: Nov. 26, 2025

(30) Foreign Application Priority Data
Dec. 20, 2024 (KR) 10-2024-0192750

(51) Int. Cl. G09G 3/20; G09G 3/3233

(52) U.S. Cl. CPC G09G 3/2074; G09G 3/3233; G09G 2300/0408; G09G 2300/0804; G09G 2300/0819; G09G 2300/0852; G09G 2310/0286; G09G 2310/0289; G09G 2310/08; G09G 2320/0233; G09G 2320/0666; G09G 2330/023

(57) ABSTRACT

A display panel and a display device including the same are discussed, in which a reference voltage line is additionally disposed to reduce a sensing time of a pixel. The display panel includes a first reference voltage line for supplying a reference voltage to at least one sub-pixel of a first pixel, a second reference voltage line for supplying a reference voltage to at least one sub-pixel of a second pixel disposed at a position adjacent to the first pixel, and a third reference voltage line disposed between the first pixel and the second pixel, thereby shortening a sensing time of the pixel and reducing power consumption.

### CROSS REFERENCE TO RELATED APPLICATION

The present application claims priority to Korean Patent Application No. 10-2024-0192750, filed in the Republic of Korea on Dec. 20, 2024, the entire contents of which is hereby expressly incorporated by reference for all purposes.

### BACKGROUND OF THE DISCLOSURE

### Field

The present disclosure relates to a display device, and more particularly, to a display panel in which reference voltage lines are arranged so as to reduce a time taken for sensing sub-pixels, and to a display device including the same.

### Discussion of the Related Art

Display devices used in a computer monitor, a television (TV), a mobile phone, or the like include an organic light-emitting display device (OLED) that emits light by itself, and a liquid crystal display device (LCD) that requires a separate light source.

Among these various display devices, the organic light-emitting display device includes a display panel including a plurality of sub-pixels and a driver for driving the display panel. The driver includes a gate driver for supplying a gate signal to the display panel and a data driver for supplying a data voltage. When a signal such as a gate signal and a data voltage is supplied to a sub-pixel of the organic light-emitting display device, the selected sub-pixel can emit light to display an image.

### SUMMARY OF THE DISCLOSURE

A conventional display panel has a problem in that the time taken for sensing a pixel can increase.

Accordingly, there is a need to provide a display panel that shortens the time taken for sensing a pixel and shortens the compensation time of the display panel.

Conventionally, the number of the data lines and a multiple of the number of the reference voltage lines are equal to each other such that the time taken for sensing a pixel increases.

Accordingly, the inventors of the present disclosure have invented a display panel capable of reducing a time taken for sensing a pixel and a display device including the same.

A purpose of an aspect of the present disclosure is to provide a display panel in which reference voltage lines are arranged such that the number of the data lines for transmitting a data voltage to a sub-pixel of the display panel is equal to a multiple of the number of the reference voltage lines, thereby reducing a time taken for sensing a plurality of sub-pixels disposed in one row.

Another purpose of an aspect of the present disclosure is to provide a display panel in which a first reference voltage line for supplying a reference voltage to at least one sub-pixel of a first pixel is disposed, a second reference voltage line for supplying a reference voltage to at least one sub-pixel of a second pixel disposed at a position adjacent to the first pixel is disposed, and a third reference voltage line is disposed between the first pixel and the second pixel, thereby shortening a time taken for sensing a plurality of sub-pixels.

Another purpose of an aspect of the present disclosure is to provide a display panel including a plurality of reference voltage lines arranged such that one reference voltage line is disposed every two sub-pixels of each of the plurality of pixels, thereby shortening a sensing time.

Another purpose of an aspect of the present disclosure is to provide a display panel in which a high potential voltage line is divided into a plurality of sub-high potential voltage lines, and a high potential voltage is applied using each of the sub-high potential voltage lines.

According to an embodiment of the present disclosure, in order to shorten a sensing time of a pixel, a display panel in which a first reference voltage line for supplying a reference voltage to at least one sub-pixel of a first pixel is disposed, a second reference voltage line for supplying a reference voltage to at least one sub-pixel of a second pixel disposed at a position adjacent to the first pixel is disposed, and a third reference voltage line is additionally disposed between the first pixel and the second pixel, and a display device including the display panel are provided.

According to an embodiment of the present disclosure, provided are a display panel in which a third reference voltage line is disposed between a first reference voltage line and a second reference voltage line in an arrangement of a 2×2 pixel, and a display device including the same.

According to an embodiment of the present disclosure, a display panel in which a first reference voltage line, a second reference voltage line, and a third reference voltage are disposed to transmit a reference voltage to the sub-pixels R, G, and B of the first pixel and the sub-pixels R, G, and B of the second pixel, and a display device including the same are provided.

According to an embodiment of the present disclosure, provided are a display panel in which a first reference voltage line is disposed between a first sub-pixel of a first pixel and a second sub-pixel thereof adjacent to the first sub-pixel, and a display device including the same.

According to an embodiment of the present disclosure, provided are a display panel in which a second reference voltage line is disposed between a second sub-pixel of a second pixel and a third sub-pixel thereof adjacent to the second sub-pixel, and a display device including the same.

According to an embodiment of the present disclosure, provided are a display panel in which a third reference voltage line is disposed between a third sub-pixel of a first pixel and a first sub-pixel of a second pixel, and a display device including the same.

According to an embodiment of the present disclosure, there are provided a display panel in which sub-pixels of the adjacent pixels are alternately arranged with each other in the row direction in a manner flipped relative to each other in the column direction, and a display device including the same.

According to an embodiment of the present disclosure, a display panel in which two reference voltage lines are disposed in each of a plurality of pixels, and a display device including the same are provided.

According to an embodiment of the present disclosure, a display panel in which a driving circuit is disposed on one or the other of both opposing sides in the column direction of the light-emitting area of each of sub-pixels of each of a plurality of pixels and the display panel operates in a single rate driving (SRD) manner and a display device including the same are provided.

According to an embodiment of the present disclosure, there are provided a display panel in which a first pixel and a second pixel disposed at a position adjacent to the first pixel are alternately arranged with each other in the row direction in a manner flipped relative to each other in the column direction, and a display device including the same.

According to an embodiment of the present disclosure, the reference voltage lines are provided in the display panel such that the multiple of the number of the reference voltage lines and the number of the data lines are equal to each other, thereby reducing the time taken for sensing the pixel.

According to an embodiment of the present disclosure, a first reference voltage line for supplying a reference voltage to at least one sub-pixel of a first pixel is disposed, a second reference voltage line for supplying a reference voltage to at least one sub-pixel of a second pixel disposed at a position adjacent to the first pixel is disposed, and a third reference voltage line is disposed between the first pixel and the second pixel, thereby reducing a time taken for sensing a plurality of sub-pixels disposed in one row.

According to another embodiment of the present disclosure, the third reference voltage is supplied to each of at least one sub-pixel in the first pixel and at least one sub-pixel in the second pixel, thereby reducing a time taken for sensing the plurality of sub-pixels disposed in one row.

According to another embodiment of the present disclosure, the third reference voltage line is disposed between the first pixel and the second pixel, such that the reference voltage can be supplied to each of the third sub-pixel of the first pixel and the first sub-pixel of the second pixel.

According to another embodiment of the present disclosure, in the display panel to which double rate driving (DRD) scheme is applied, the multiple of the number of the reference voltage lines is equal to the number of the data lines, such that the compensation time of the display panel can be shortened, and accordingly, the image quality can be improved.

According to another embodiment of the present disclosure, the third reference voltage line is disposed between the first pixel and the second pixel adjacent to each other, the sensing time can be reduced by 33% in the single rate driving (SRD).

According to another embodiment of the present disclosure, the third reference voltage line is disposed between the first pixel and the second pixel, such that the sensing time can be reduced by 50% in the DRD.

According to another embodiment of the present disclosure, the third reference voltage line is disposed between the first pixel and the second pixel, such that the compensation time affecting the image quality can be shortened.

According to another embodiment of the present disclosure, the compensation time affecting the image quality can be shortened such that the display device operates at a lower power level. The power consumption can be reduced. The greenhouse effect is lowered.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF THE DRAWINGS

FIG. 1 is a schematic diagram of a display device according to an embodiment of the present disclosure.

FIG. 2 is a circuit diagram of a sub-pixel of a display device according to an embodiment of the present disclosure.

FIG. 3 is an example diagram illustrating an arrangement relationship of sub-pixels of a display device according to an embodiment of the present disclosure.

FIG. 4 is a timing diagram of a gate voltage and a data voltage when a display device according to an embodiment of the present disclosure implements a monochromatic still screen.

FIG. 5 is a timing diagram of a gate voltage and a data voltage when a display device according to an embodiment of the present disclosure implements a vertical pattern screen.

FIG. 6 is an example diagram illustrating a sensing sequence of a plurality of sub-pixels according to an embodiment of the present disclosure.

FIG. 7 is a first example diagram illustrating an arrangement relationship of sub-pixels when a pixel of a display panel according to an embodiment of the present disclosure has three sub-pixels.

FIG. 8 is an example diagram illustrating a sensing sequence of a plurality of sub-pixels in FIG. 7.

FIG. 9 is a second example diagram illustrating an arrangement relationship of sub-pixels when a pixel of a display panel according to an embodiment of the present disclosure has three sub-pixels.

FIG. 10 is an example diagram illustrating a sensing sequence of a plurality of sub-pixels in FIG. 9.

FIG. 11 is a timing diagram of a gate voltage, a data voltage, and a voltage charged into a storage capacitor according to an embodiment of the present disclosure.

FIG. 12 is a first example diagram illustrating an arrangement relationship of sub-pixels when a pixel of a display panel according to embodiments of the present disclosure has four sub-pixels.

FIG. 13 is an example diagram illustrating a sensing sequence of a plurality of sub-pixels in FIG. 12 according to an example embodiment of the present disclosure.

FIG. 14 is a second example diagram illustrating an arrangement relationship of sub-pixels when each of pixels of the display panel according to embodiments of the present disclosure has four sub-pixels.

FIG. 15 is an example diagram illustrating a sensing sequence of a plurality of sub-pixels in FIG. 14.

FIG. 16 is a third example diagram illustrating an arrangement relationship of sub-pixels when each of pixels of the display panel according to embodiments of the present disclosure has four sub-pixels.

FIG. 17 is an example diagram illustrating a sensing sequence of a plurality of sub-pixels in FIG. 16.

FIG. 18 is a timing diagram of a gate voltage, a data voltage, and a voltage charged into a storage capacitor according to an embodiment of the present disclosure according to FIG. 17.

FIG. 19 is a fourth example diagram illustrating an arrangement relationship of sub-pixels when each of pixels of the display panel according to embodiments of the present disclosure has four sub-pixels.

FIG. 20 is an example diagram illustrating a sensing sequence of a plurality of sub-pixels in FIG. 19.

FIG. 21 is a timing diagram of a gate voltage, a data voltage, and a voltage charged into a storage capacitor according to an embodiment of the present disclosure according to FIG. 20.

### DETAILED DESCRIPTION OF THE DISCLOSURE

Advantages and features of the present disclosure, and a method of achieving the advantages and features will become apparent with reference to embodiments described below in detail together with the accompanying drawings. However, the present disclosure is not limited to the embodiments as disclosed below, but can be implemented in various different forms. Thus, these embodiments are set forth only to make the present disclosure complete, and to entirely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included within the spirit and scope of the present disclosure as defined by the appended claims. Further, the term “can” fully encompasses all the meanings and coverages of the term “may” and vice versa.

A shape, a size, a ratio, an angle, a number, etc. disclosed in the drawings for illustrating embodiments of the present disclosure are illustrative, and the present disclosure is not limited thereto. The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements can modify an entirety of the list of elements and may not modify the individual elements of the list.

In interpretation of numerical values, an error or tolerance therein can occur even when there is no explicit description thereof.

In addition, it will also be understood that when a first element or layer is referred to as being present “on” a second element or layer, the first element can be disposed directly on the second element or can be disposed indirectly on the second element with a third element or layer being disposed between the first and second elements or layers. It will be understood that when a first element or layer is referred to as being “connected to”, or “coupled to” a second element or layer, the first element can be directly connected to or coupled to the second element or layer, or one or more intervening elements or layers can be present therebetween. In addition, it will also be understood that when an element or layer is referred to as being “between” two elements or layers, it can be the only element or layer between the two elements or layers, or one or more intervening elements or layers can also be present therebetween.

Further, as used herein, when a layer, film, area, plate, or the like is disposed “on” or “on a top” of another layer, film, area, plate, or the like, the former can directly contact the latter or still another layer, film, area, plate, or the like can be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former can directly contact the latter or still another layer, film, area, plate, or the like can be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is not indicated. When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms such as “first”, “second”, “third”, and so on can be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described below could be termed a second element, component, area, layer or section, without departing from the spirit and scope of the present disclosure.

When an embodiment of the present disclosure can be implemented differently, functions or operations specified within a specific block can be performed in a different order from an order specified in a flowchart. For example, two consecutive blocks can actually be performed substantially simultaneously, or the blocks can be performed in a reverse order depending on related functions or operations.

The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range even there is no separate explicit description thereof. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects”, etc. should not be construed such that any aspect or design as described is superior to or advantageous over other aspects or designs. Further, the term ‘or’ means ‘inclusive or’ rather than ‘exclusive or'. That is, unless otherwise stated or clear from the context, the expression that 'x uses a or b’ means one of natural inclusive permutations.

The terms used in the description as set forth below have been selected as being general and universal in the related technical field. However, there can be other terms than the terms depending on the development and/or change of technology, convention, preference of technicians, etc. Therefore, the terms used in the description as set forth below should not be understood as limiting technical ideas, but should be understood as examples of the terms for illustrating embodiments. Further, in a specific case, a term can be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Description section.

In description of flow of a signal, for example, when a signal is delivered from a node A to a node B, this can include a case where the signal is transferred from the node A to the node B via another node unless a phrase ‘immediately transferred’ or ‘directly transferred’ is used. Throughout the present disclosure, “A and/or B” means A, B, or A and B, unless otherwise specified, and “C to D” means C inclusive to D inclusive unless otherwise specified.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but can be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure can work functionally. In a plan view of the display device, a column direction and a row direction intersecting each other are used to define an extension direction of a component, for example, a line.

A transistor used in the display device of the present disclosure can be embodied as one or more transistors of an n-channel transistor NMOS and a p-channel transistor PMOS. The transistor can be embodied as an oxide semiconductor transistor having an oxide semiconductor layer as an active layer or a LTPS transistor having a low temperature poly-silicon (LTPS) layer as an active layer. The transistor can include at least a gate electrode, a source electrode, and a drain electrode. The transistor can be embodied as a thin-film transistor (TFT) on the display panel. The carriers in the transistor flow from the source electrode to the drain electrode. In the n-channel transistor NMOS, since the carriers are electrons, the source voltage is lower than the drain voltage so that electrons can flow from the source electrode to the drain electrode. In the n-channel transistor NMOS, the current flows from the drain electrode to the source electrode, and the source electrode can be an output terminal. In the p-channel transistor PMOS, since the carrier is a hole, the source voltage is higher than the drain voltage so that the hole can flow from the source electrode to the drain electrode. In the p-channel transistor PMOS, since holes flow from the source electrode to the drain electrode, a current flows from the source electrode to the drain electrode, and the drain electrode can be an output terminal. Therefore, it should be noted that the source and the drain of the transistor are not fixed because the source and the drain can be exchanged with each other based on the applied voltage. In the present disclosure, it is assumed that the transistor is an n-channel transistor (NMOS). However, embodiments of the present disclosure are not limited thereto, and the transistor can be embodied as an p-channel transistor, and accordingly, a circuit configuration can be changed.

A gate signal of a transistor used as each of switch elements swings between a gate-on voltage and a gate-off voltage. The gate-on voltage is set to a voltage higher than the threshold voltage Vth of the transistor, and the gate-off voltage is set to a voltage lower than the threshold voltage Vth of the transistor. The transistor is turned on in response to the gate-on voltage, while being turned off in response to the gate-off voltage. In the NMOS, the gate-on voltage can be the gate high voltage VGH, and the gate-off voltage can be the gate low voltage VGL. In the PMOS, the gate-on voltage can be the gate low voltage VGL, and the gate-off voltage can be the gate high voltage VGH.

Hereinafter, various embodiments of the present disclosure will be described in detail with reference to the accompanying drawings. All the components of each display device/apparatus according to all embodiments of the present disclosure are operatively coupled and configured.

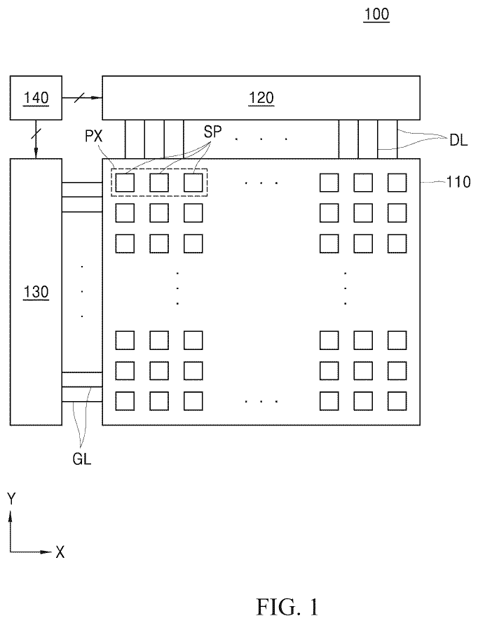

FIG. 1 is a schematic diagram of a display device according to an embodiment of the present disclosure.

Referring to FIG. 1, a display device 100 according to an embodiment of the present disclosure can include a display panel 110, a data driver 120, a gate driver 130, and a timing controller 140.

The configuration of the display panel 110 illustrated in FIG. 1 is merely according to an embodiment of the present disclosure, and the components of the display panel 110 are not limited to those in the embodiment as illustrated in FIG. 1, and some components can be added, changed, or deleted as necessary.

According to an embodiment of the present disclosure, the display panel 110 is a panel for displaying an image. The display panel 110 can include various circuits, lines, and light-emitting elements disposed on a substrate. An area of the display panel 110 can divide into pixels areas defined by a plurality of data lines DL and a plurality of gate lines GL intersecting each other, and can include a plurality of pixels PX respectively disposed in the pixel areas and connected to the plurality of data lines DL and the plurality of gate lines GL.

The display panel 110 can include a display area including the plurality of pixels PX and a non-display area in which various signal lines or pads are formed.

The display panel 110 can be embodied as a display panel 110 used in various display devices such as a liquid crystal display device, an organic light-emitting display device, an electrophoretic display device, and the like.

Hereinafter, an example is described in which the display panel 110 is a panel used in an organic light-emitting display device. However, embodiments of the present disclosure are not limited thereto.

According to an embodiment of the present disclosure, the timing controller 140 can receive a timing signal such as a vertical synchronization signal, a horizontal synchronization signal, a data enable signal, and a dot clock via a receiving circuit such as an LVDS or TMDS interface connected to a host system. The timing controller 140 can generate timing control signals for controlling the data driver 120 and the gate driver 130 based on the input timing signal.

According to an embodiment of the present disclosure, the data driver 120 can supply a data voltage DATA to the plurality of sub-pixels SP. The data driver 120 can include a plurality of source drive integrated circuits (IC). The plurality of source drive IC can receive digital video data and a source timing control signal from the timing controller 140.

The plurality of source drive ICs can convert the digital video data into a gamma voltage in response to the source timing control signal to generate the data voltage DATA, and can supply the data voltage DATA via the data line DL of the display panel 110. The plurality of source drive ICs can be connected to the data line DL of the display panel 110 in a chip on glass (COG) process or a tape automated bonding (TAB) process.

In addition, the source drive ICs can be formed on the display panel 110, or can be formed on a separate PCB substrate which can be connected to the display panel 110.

According to an embodiment of the present disclosure, the gate driver 130 can supply a gate signal to the plurality of sub-pixels SP. The gate driver 130 can include a level shifter and a shift register. The level shifter can shift a level of a clock signal input from the timing controller 140 to a transistor-transistor-logic (TTL) level and then supply the signal having the shifted level to the shift register. The shift register can be formed in the non-display area of the display panel 110 in an GIP (gate in panel) manner. However, embodiments of the present disclosure are not limited thereto.

The shift register can include a plurality of stages that shift and output the gate signal in response to the clock signal and a driving signal. The plurality of stages included in the shift register can sequentially output the gate signal via a plurality of output terminals.

According to an embodiment of the present disclosure, the display panel 110 can include a plurality of sub-pixels SP. The plurality of sub-pixels SP can be sub-pixels SP for emitting light of different colors. For example, the plurality of sub-pixels SP can include a red sub-pixel, a green sub-pixel, and a blue sub-pixel. However, embodiments of the present disclosure are not limited thereto. The plurality of sub-pixels SP can constitute the pixel PX.

In one example, a first pixel of the display panel 110 can include a plurality of sub-pixels, and a second pixel thereof can include a plurality of sub-pixels. In addition, the second pixel can be disposed at a position adjacent to the first pixel in the first direction (e.g., the x-axis direction).

Furthermore, a second sub-pixel of the first pixel can be disposed at a position adjacent to a first sub-pixel of the first pixel in the first direction (e.g., the x-axis direction). In addition, a third sub-pixel of the first pixel can be disposed at a position adjacent to the second sub-pixel of the first pixel in the first direction (e.g., the x-axis direction).

In addition, the plurality of sub-pixels SP of the display panel 110 according to the present disclosure can include a red sub-pixel, a green sub-pixel, and a blue sub-pixel. However, embodiments of the present disclosure are not limited thereto.

That is, the red sub-pixel, the green sub-pixel, and the blue sub-pixel can constitute one pixel PX, and the display panel 110 can include a plurality of pixels PX.

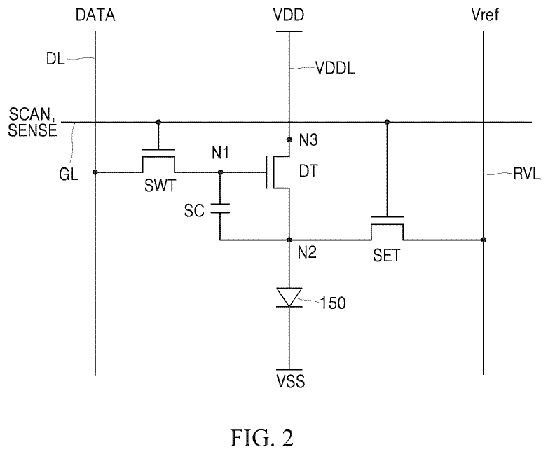

Hereinafter, for a more detailed description of a driving circuit for driving one sub-pixel SP, FIG. 2 will be referred to together with FIG. 1.

FIG. 2 is a circuit diagram of a sub-pixel of a display device according to an embodiment of the present disclosure.

For example, FIG. 2 illustrates a circuit diagram of one sub-pixel SP among the plurality of sub-pixels SP of the display device 100. Each sub-pixel of FIG. 1 can have the configuration of FIG. 2.

Referring to FIG. 2, the sub-pixel SP can include a switching transistor SWT, a sensing transistor SET, a driving transistor DT, a storage capacitor SC, and a light-emitting element 150.

According to an embodiment of the present disclosure, the light-emitting element 150 can include an anode, an organic layer stack, and a cathode. The organic layer stack can include a stack of various organic layers such as a hole injection layer, a hole transport layer, an organic light-emitting layer, an electron transport layer, and an electron injection layer. The anode of the light-emitting element 150 can be connected to an output terminal of the driving transistor DT, and a low potential voltage VSS can be applied to the cathode of the light-emitting element 150.

Although FIG. 2 illustrates that the light-emitting element 150 is embodied as the organic light-emitting element 150, the present disclosure is not limited thereto, and an inorganic light-emitting diode, that is, LED, can also be used as the light-emitting element 150.

The switching transistor SWT is a transistor for transferring the data voltage DATA to a first node N1 connected to a gate electrode of the driving transistor DT. The switching transistor SWT can include a drain electrode connected to the data line DL, a gate electrode connected to the gate line GL, and a source electrode connected to the gate electrode of the driving transistor DT. The switching transistor SWT can be turned on based on a gate voltage GATE applied from the gate line GL to transmit the data voltage DATA supplied from the data line DL to the first node N1 connected to the gate electrode of the driving transistor DT.

The driving transistor DT is a transistor for driving the light-emitting element 150 by supplying a driving current to the light-emitting element 150. The driving transistor DT can include a gate electrode connected to the first node N1, a source electrode connected to a second node N2 and corresponding to an output terminal, and a drain electrode connected to a third node N3 and corresponding to an input terminal.

The gate electrode of the driving transistor DT can be connected to the switching transistor SWT, a drain electrode thereof can receive a high potential voltage VDD via a high potential voltage line VDDL, and a source electrode thereof can be connected to the anode of the light-emitting element 150.

The storage capacitor SC is a capacitor for maintaining a voltage corresponding to the data voltage DATA for one frame. One electrode of the storage capacitor SC can be connected to the first node N1, and the other electrode thereof can be connected to the second node N2.

In one example, in the display device 100, as an operation time of each sub-pixel SP increases, degradation of a circuit element such as the driving transistor DT can proceed. Accordingly, an intrinsic characteristic value of the circuit element such as the driving transistor DT can be changed.

In this regard, the intrinsic characteristic value of the circuit element can include the threshold voltage Vth of the driving transistor DT, the mobility α of the driving transistor DT, etc. The change in the intrinsic characteristic value of the circuit element can cause a change in luminance of the corresponding sub-pixel SP.

Therefore, the change in the intrinsic characteristic value of the circuit element can be used as the same concept as the change in the luminance of the sub-pixel SP.

In addition, the change amount in the intrinsic characteristic value of the circuit element of each sub-pixel SP can vary depending on the deterioration amount of each circuit element. Thus, the change amounts in the intrinsic characteristic value of the circuit elements of different sub-pixels SP having the different deterioration amounts of the circuit elements thereof can be different from each other. Such a difference between the change amounts in the intrinsic characteristic value of the respective circuit elements of the sub-pixels can cause a luminance deviation between luminance of the sub-pixels SP.

Therefore, the deviation between the intrinsic characteristic value of the circuit elements of the different sub-pixels SP can be used as the same concept as the luminance deviation between the luminance of the different sub-pixels SP.

The change in the intrinsic characteristic value of the circuit element, that is, the change in the luminance of the sub-pixel SP and the deviations between in the intrinsic characteristic values of the circuit elements of the sub-pixels, that is, the deviation between the luminance of the sub-pixels SP, can cause problems such as a decrease in accuracy of the luminance realized in the sub-pixel SP or a screen abnormality.

In the sub-pixel SP of the display device 100 according to an embodiment of the present disclosure, a sensing function of sensing the intrinsic characteristic value of the sub-pixel SP and a compensation function of compensating for the intrinsic characteristic value of the sub-pixel SP based on the sensing result can be provided.

Accordingly, as shown in FIG. 2, the sub-pixel SP can further include a sensing transistor SET for effectively controlling the voltage state of the source electrode of the driving transistor DT in addition to the switching transistor SWT, the driving transistor DT, the storage capacitor SC, and the light-emitting element 150.

Referring to FIG. 2, the sensing transistor SET is connected to and disposed between the source electrode of the driving transistor DT and a reference voltage line RVL that supplies a reference voltage Vref. A gate electrode of the sensing transistor SET is connected to the gate line GL. Accordingly, the sensing transistor SET can be turned on based on the sensing signal SENSE applied via the gate line GL to apply the reference voltage Vref supplied via the reference voltage line RVL to the source electrode of the driving transistor DT. In addition, the sensing transistor SET can be used as one of voltage sensing paths for the source electrode of the driving transistor DT.

The switching transistor SWT and the sensing transistor SET of the sub-pixel SP can share one gate line GL. That is, the switching transistor SWT and the sensing transistor SET can be connected to the same gate line GL and can receive the same gate signal therefrom. However, for convenience of description, a voltage applied to the gate electrode of the switching transistor SWT is referred to as the gate voltage GATE, and a voltage applied to the gate electrode of the sensing transistor SET is referred to as a sensing signal SENSE. However, the gate voltage GATE and the sensing signal SENSE applied to one sub-pixel SP are the same signal transmitted via the same gate line GL.

However, the present disclosure is not limited thereto, and only the switching transistor SWT can be connected to the gate line GL, and the sensing transistor SET can be connected to a separate sensing line. Accordingly, the gate voltage GATE can be applied to the switching transistor SWT via the gate line GL, and the sensing signal SENSE can be applied to the sensing transistor SET via the sensing line.

Accordingly, the reference voltage Vref is applied to the source electrode of the driving transistor DT via the sensing transistor SET. In addition, a voltage for sensing the threshold voltage Vth of the driving transistor DT or the mobility α of the driving transistor DT is detected via the reference voltage line RVL. In addition, the data driver 120 can compensate for the data voltage DATA based on an amount of change in the detected threshold voltage Vth of the driving transistor DT or the detected mobility α of the driving transistor DT.

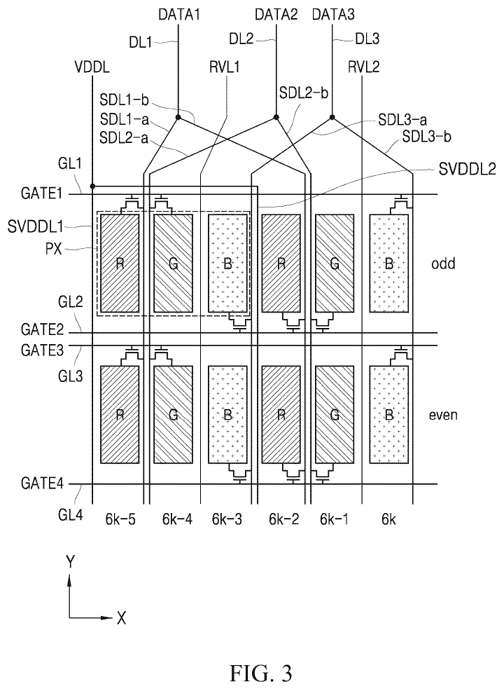

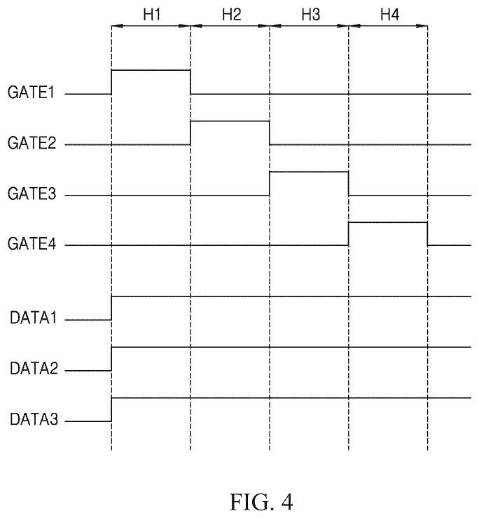

Hereinafter, FIGS. 3 and 4 are referred together to describe an arrangement relationship of a plurality of sub-pixels.

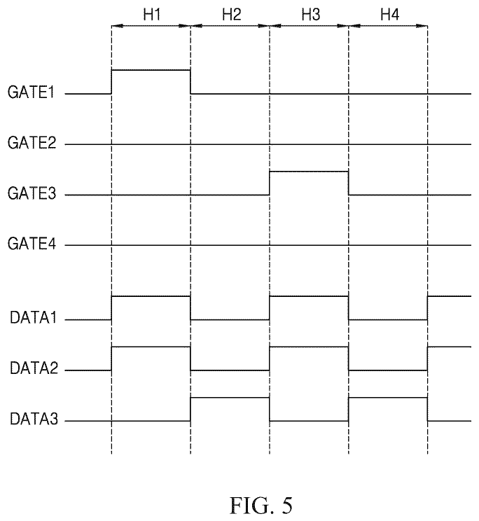

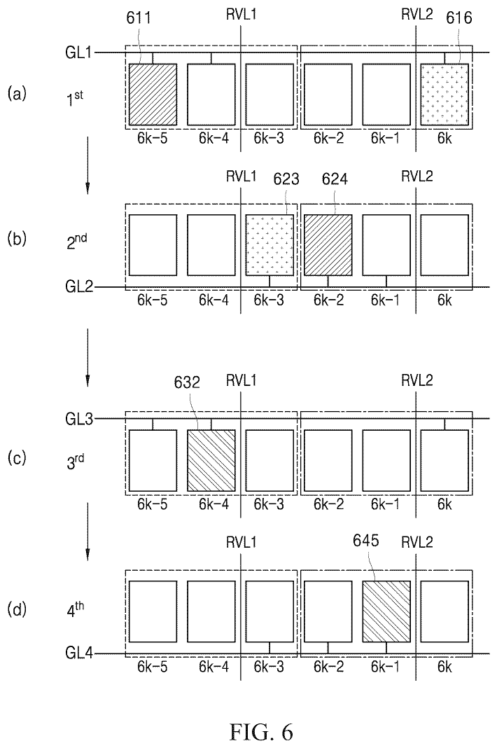

FIG. 3 is an example diagram illustrating an arrangement relationship of sub-pixels of a display device according to an embodiment of the present disclosure. FIG. 4 is a timing diagram of a gate voltage and a data voltage when a display device according to an embodiment of the present disclosure displays a monochromatic still screen. FIG. 5 is a timing diagram of a gate voltage and a data voltage when a display device according to an embodiment of the present disclosure displays a vertical pattern screen. FIG. 6 is an example diagram illustrating a sensing sequence of a plurality of sub-pixels according to an embodiment of the present disclosure.

For convenience of description, only four pixels PX arranged in a 2×2 matrix form are illustrated in FIG. 3. In an arrangement relationship of four pixels PX arranged in a 2×2 matrix form in the display area DA, the sub-pixels of the two pixels PX in the same row can be alternately arranged with each other in the row direction in a manner flipped relative to each other in a column direction. In addition, a transistor disposed between the adjacent sub-pixels R, G, and B and the data line means the switching transistor SWT described in FIG. 2.

According to an embodiment of the present disclosure, each of the plurality of data lines DL1, DL2 and DL3 can divide into a plurality of sub-data lines SDL1-a and SDL1-b, SDL2-a and SDL2-b, or SDL3-a and SDL3-b.

In one example, the first data line DL1 can divide into a plurality of first sub-data lines SDL1-a and SDL1-b, and the second data line DL2 can divide into a plurality of second sub-data lines SDL2-a and SDL2-b.

The third data line DL3 can divide into the plurality of third sub-data lines SDL3-a and SDL3-b.

According to an embodiment of the present disclosure, the first sub-data lines SDL1-a and SDL1-b can include a (1-a)th sub-data line SDL1-a and a (1-b)th sub-data line SDL1-b, and the second sub-data lines SDL2-a and SDL2-b can include a (2-a)th sub-data line SDL2-a and a (2-b)th sub-data line SDL2-b.

The third sub-data lines SDL3-a and SDL3-b can include a (3-a)th sub-data line SDL3-a and a (3-b)th sub-data line SDL3-b.

According to an embodiment of the present disclosure, the high-potential voltage line VDDL can be disposed on one side (e.g., the left side) of the first pixel and can divide into two sub-high-potential voltage lines SVDDL1 and SVDDL2. Each sub-high-potential voltage line can be disposed between adjacent ones of a plurality of pixels PX.

According to an embodiment of the present disclosure, one pixel PX can include three sub-pixels R, G, and B. For example, as shown in FIG. 3, the pixel PX can include a first sub-pixel R, a second sub-pixel G, and a third sub-pixel B. For example, the first sub-pixel R can be a red sub-pixel, the second sub-pixel G can be a green sub-pixel, and the third sub-pixel B can be a blue sub-pixel. However, embodiments of the present disclosure are not limited thereto, and the plurality of sub-pixels may include sub-pixels emitting light of various colors such as magenta, yellow, and cyan, etc.

According to an embodiment of the present disclosure, the second sub-pixel G of the first pixel can be disposed at a position adjacent to the first sub-pixel R of the first pixel in the first direction (e.g., the x-axis direction). In addition, the third sub-pixel B of the first pixel can be disposed at a position adjacent to the second sub-pixel G of the first pixel in the first direction (e.g., the x-axis direction). Herein, the second sub-pixel G may be referred to as “a first line-sub-pixel”, and the third sub-pixel B may be referred to as “a second line-sub-pixel”.

In addition, the plurality of sub-pixels emitting light of the same color can be arranged in the same column. That is, the plurality of first sub-pixels R can be arranged in the same column, the plurality of second sub-pixels G can be arranged in the same column, and the plurality of third sub-pixels B can be arranged in the same column.

More specifically, as illustrated in FIG. 3, the plurality of first sub-pixels R can be arranged in each of a (6k-5)th column and a (6k-2)th column, and the plurality of second sub-pixels G can be arranged in each of a (6k-4)th column and a (6k-1)th column. In addition, the plurality of third sub-pixels B can be arranged in each of a (6k-3)th column and a 6k-th column. In this regard, k means a natural number greater than or equal to 1. The arrangement of the sub-pixels according to the present disclosure is not limited to FIG. 3.

That is, the first sub-pixel R, the second sub-pixel G, and the third sub-pixel B can be sequentially and repeatedly arranged along one odd-numbered row odd or one even-numbered row even.

According to an embodiment of the present disclosure, the sub-pixels of the first pixel and the second pixel disposed adjacent to each other in the first direction (e.g., the x-axis direction) can be alternately arranged with each other in the row direction in a manner flipped relative to each other in a column direction.

According to an embodiment of the present disclosure, the plurality of first sub-data lines SDL1-a and SDL1-b can be disposed adjacent to the plurality of first sub-pixels R so as to be connected to the plurality of first sub-pixels R.

Specifically, the (1-a)th sub-data line SDL1-a can be disposed between the plurality of first sub-pixels R arranged in the (6k-5)th column and the plurality of second sub-pixels G arranged in the (6k-4)th column, and can be electrically connected to the plurality of first sub-pixels R arranged in the (6k-5)th column. In addition, the (1-b)th sub-data line SDL1-b can be disposed between the plurality of first sub-pixels R arranged in the (6k-2)th column and the plurality of second sub-pixels G arranged in the (6k-1)th column, and can be electrically connected to the plurality of first sub-pixels R arranged in the (6k-2)th column.

According to an embodiment of the present disclosure, the plurality of second sub-data lines SDL2-a and SDL2-b can be disposed adjacent to the plurality of second sub-pixels G and can be connected to the plurality of second sub-pixels G.

Specifically, the (2-a)th sub-data line SDL2-a can be disposed between the plurality of first sub-pixels R arranged in the (6k-5)th column and the plurality of second sub-pixels G arranged in the (6k-4)th column, and can be electrically connected to the plurality of second sub-pixels G arranged in the (6k-4)th column. In addition, the (2-b)th sub-data line SDL2-b can be disposed between the plurality of first sub-pixels R arranged in the (6k-2)th column and the plurality of second sub-pixels G arranged in the (6k-1)th column, and can be electrically connected to the plurality of second sub-pixels G arranged in the (6k-1)th column.

According to an embodiment of the present disclosure, the plurality of third sub-data lines SDL3-a and SDL3-b can be disposed adjacent to the plurality of third sub-pixels B and can be connected to the plurality of third sub-pixels B.

Specifically, the (3-a)th sub-data line SDL3-a can be disposed between the plurality of third sub-pixels B arranged in the (6k-3)th column and the plurality of first sub-pixels R arranged in the (6k-2)th column, and can be electrically connected to the plurality of third sub-pixels B arranged in the (6k-3)th column. In addition, the (3-b)th sub-data line SDL3-b can be electrically connected to the plurality of third sub-pixels B arranged in the 6k-th column.

According to an embodiment of the present disclosure, a first data voltage DATA1 as a red data voltage can be applied to the first data line DL1, and a second data voltage DATA2 as a green data voltage can be applied to the second data line DL2. In addition, a third data voltage DATA3 as a blue data voltage can be applied to the third data line DL3.

Accordingly, the first data voltage DATA1 as a red data voltage can also be applied to the plurality of first sub-data lines SDL1-a and SDL1-b, and the second data voltage DATA2 as a green data voltage can also be applied to the plurality of second sub-data lines SDL2-a and SDL2-b. In addition, the third data voltage DATA3 as a blue data voltage can also be applied to the plurality of third sub-data lines SDL3-a and SDL3-b.

According to an embodiment of the present disclosure, each of the plurality of gate lines GL1 to GL4 can be respectively disposed on each of both opposing sides in the column direction (e.g., upper and lower sides in the drawing) of each of the first and second rows of the plurality of sub-pixels R, G, and B. The two gate lines GL2 and GL3 can be disposed between the first and second rows of the plurality of sub-pixels R, G, and B.

Specifically, referring to FIG. 3, the first gate line GL1 and the second gate line GL2 can be respectively disposed on both opposing sides in the column direction (e.g., upper and lower sides in the drawing) of the plurality of sub-pixels R, G, and B of the odd-numbered row, while the third gate line GL3 and the fourth gate line GL4 can be respectively disposed on both opposing sides in the column direction (e.g., upper and lower sides in the drawing) of the plurality of sub-pixels R, G, and B of the even-numbered row. Accordingly, the second gate line GL2 and the third gate line GL3 can be disposed between the plurality of sub-pixels R, G, and B of the odd-numbered row and the plurality of sub-pixels R, G, and B of the even-numbered row.

In one example, the plurality of pixels PX can be connected to different gate lines GL1 to GL4.

Specifically, the sub-pixels R and G respectively disposed in the (6k-5)th column and the (6k-4)th column of the odd-numbered row odd can be connected to the first gate line GL1. The sub-pixel B disposed in the (6k-3)th column of the odd-numbered row odd can be connected to the second gate line GL2. In addition, the sub-pixels R and G respectively disposed in the (6k-2)th column and the (6k-1)th column of the odd-numbered row odd can be connected to the second gate line GL2, and the sub-pixel B disposed in the 6k-th column of the odd-numbered row odd can be connected to the first gate line GL1. As described above, the sub-pixels of the pixels PX of the display panel 110 according to the present disclosure can be alternately arranged with each other in the row direction in a manner flipped relative to each other in a column direction.

In addition, the sub-pixels R and G respectively disposed in the (6k-5)th column and the (6k-4)th column of the even-numbered row even can be connected to the third gate line GL3, and the sub-pixel B disposed in the (6k-3)th column of the even-numbered row even can be connected to the fourth gate line GL4. In addition, the sub-pixels R and G respectively disposed in the (6k-2)th column and the (6k-1)th column of the even-numbered row even can be connected to the fourth gate line GL4. The sub-pixel B disposed in the 6k-th column of the even-numbered row even can be connected to the third gate line GL3.

According to an embodiment of the present disclosure, each of the plurality of reference voltage lines RVL1 and RVL2 can be disposed inside one pixel PX, and the reference voltage line can include a first reference voltage line RVL1 and a second reference voltage line RVL2. The high potential voltage line VDDL can divide into two sub-high potential voltage lines SVDDL1 and SVDDL2, and each sub-high potential voltage line can be disposed between the adjacent pixels.

For example, the first sub-high potential voltage line SVDDL1 can be disposed on the left side of the first sub-pixel R arranged in the (6k-5)th column, and the second sub-high potential voltage line SVDDL2 can be disposed between the third sub-pixel B arranged in the (6k-3)th column and the first sub-pixel R arranged in the (6k-2)th column.

For example, the first reference voltage line RVL1 can be disposed between the plurality of second sub-pixels G arranged in the (6k-4)th column and the plurality of third sub-pixels B arranged in the (6k-3)th column, and the second reference voltage line RVL2 can be disposed between the plurality of second sub-pixels G arranged in the (6k-1)th column and the plurality of third sub-pixels B arranged in the 6k-th column.

According to an embodiment of the present disclosure, the high potential voltage line VDDL can divide into a plurality of sub-high potential voltage lines SVDDL1 and SVDDL2.

For example, the first sub-high potential voltage line SVDDL1 can be disposed outside (e.g., on the left side of) the plurality of first sub-pixels R arranged in the (6k-5)th column, and the second sub-high potential voltage line SVDDL2 can be disposed between the plurality of third sub-pixels B arranged in the (6k-3)th column and the plurality of first sub-pixels R arranged in the (6k-2)th column.

Hereinafter, a method for displaying a monochromatic still screen and a method of displaying a vertical pattern screen of the display device 100 according to an embodiment of the present disclosure will be described with reference to FIGS. 4 and 5.

FIG. 4 is a timing diagram of a gate voltage and a data voltage when a display device according to an embodiment of the present disclosure displays a monochromatic still screen.

As shown in FIGS. 3 and 4, a first gate voltage GATE1 is output via the first gate line GL1, a second gate voltage GATE2 is output via the second gate line GL2, a third gate voltage GATE3 is output via the third gate line GL3, and a fourth gate voltage GATE4 is output via the fourth gate line GL4.

In addition, a first data voltage DATA1 is output via the first data line DL1, a second data voltage DATA2 is output via the second data line DL2, and a third data voltage DATA3 is output via the third data line DL3.

Referring to FIG. 4, in a first horizontal period H1, the first gate voltage GATE1 is the gate high voltage, and the second gate voltage GATE2, the third gate voltage GATE3, and the fourth gate voltage GATE4 are the gate low voltages. In addition, in the first horizontal period H1, each of the first data voltage DATA1 to the third data voltage DATA3 can be a data voltage of a predetermined level for implementing a predetermined grayscale.

Accordingly, during the first horizontal period H1, all of the switching transistors respectively connected to the plurality of first sub-pixels R arranged in the (6k-5)th column, the plurality of second sub-pixels G arranged in the (6k-4)th column, and the plurality of third sub-pixels B arranged in the 6k-th column in the odd-numbered row are turned on.

Accordingly, during the first horizontal period H1, the first data voltage DATA1 can be charged into the plurality of first sub-pixels R arranged in the (6k-5)th column in the odd-numbered row odd, the second data voltage DATA2 can be charged into the plurality of second sub-pixels G arranged in the (6k-4)th column in the odd-numbered row odd, and the third data voltage DATA3 can be charged into the plurality of third sub-pixels B arranged in the 6k-3th column in the odd-numbered row odd.

In a second horizontal period H2, the second gate voltage GATE2 is the gate high voltage, and the first gate voltage GATE1, the third gate voltage GATE3, and the fourth gate voltage GATE4 are the gate low voltages. In addition, in the second horizontal period H2, each of the first data voltage DATA1 to the third data voltage DATA3 can be a data voltage of a predetermined level for implementing a predetermined grayscale.

Accordingly, during the second horizontal period H2, all of the switching transistors respectively connected to the plurality of third sub-pixels B arranged in the (6k-3)th column, the plurality of first sub-pixels R arranged in the (6k-2)th column, and the plurality of second sub-pixels G arranged in the (6k-1)th column in the odd-numbered row are turned on.

Accordingly, during the second horizontal period H 2, the third data voltage DATA 3 can be charged into the plurality of third sub-pixels B arranged in the (6k-3)th column in the odd-numbered row odd, the first data voltage DATA 1 can be charged into the plurality of first sub-pixels R arranged in the (6k-2)th column in the odd-numbered row odd, and the second data voltage DATA 2 can be charged into the plurality of second sub-pixels G arranged in the (6k-1)th column in the odd-numbered row odd.

In a third horizontal period H3, the third gate voltage GATE3 is the gate high voltage, and the first gate voltage GATE1, the second gate voltage GATE2, and the fourth gate voltage GATE4 are the gate low voltages. In addition, in the third horizontal period H3, each of the first data voltage DATA1 to the third data voltage DATA3 can be a data voltage of a predetermined level for implementing a predetermined grayscale.

During the third horizontal period H3, all of the switching transistors respectively connected to the plurality of first sub-pixels R arranged in the (6k-5)th column, the plurality of second sub-pixels G arranged in the (6k-4)th column, and the plurality of third sub-pixels B arranged in the 6k-th column in the even-numbered row even are turned on.

Accordingly, during the third horizontal period H3, the first data voltage DATA1 can be charged into the plurality of first sub-pixels R arranged in the (6k-5)th column in the even-numbered row even, the second data voltage DATA2 can be charged into the plurality of second sub-pixels G arranged in the (6k-4)th column in the even-numbered row even, and the third data voltage DATA3 can be charged into the plurality of third sub-pixels B disposed in the 6k-th column in the even-numbered row even.

In a fourth horizontal period H4, the fourth gate voltage GATE4 is the gate high voltage, and the first gate voltage GATE1, the second gate voltage GATE2, and the third gate voltage GATE3 are the gate low voltages. In addition, in the fourth horizontal period H4, each of the first data voltage DATA1 to the third data voltage DATA3 can be a data voltage of a predetermined level for implementing a predetermined grayscale.

During the fourth horizontal period H4, all of the switching transistors ST respectively connected to the plurality of third sub-pixels B arranged in the (6k-3)th column, the plurality of first sub-pixels R arranged in the (6k-2)th column, and the plurality of second sub-pixels G arranged in the (6k-1)th column in the even-numbered row even are turned on.

Accordingly, during the fourth horizontal period H4, the third data voltage DATA3 can be charged into the plurality of third sub-pixels B arranged in the (6k-3)th column in the even-numbered row even, the first data voltage DATA1 can be charged into the plurality of first sub-pixels R arranged in the (6k-2)th column in the even-numbered row even, and the second data voltage DATA2 can be charged into the plurality of second sub-pixels G arranged in the (6k-1)th column in the even-numbered row even.

As described above, when the display device 100 according to an embodiment of the present disclosure displays a monochromatic still screen, each of the first to third data voltages DATA1 to DATA3 can have the same level during the first to fourth horizontal periods H1 to H4, that is, during one frame. Accordingly, each of the first to third data voltages DATA1 to DATA3 is maintained at a constant data voltage level during one frame.

FIG. 5 is a timing diagram of a gate voltage and a data voltage when a display device according to an embodiment of the present disclosure displays a vertical pattern screen.

As illustrated in FIG. 5, in a first horizontal period H1, the first gate voltage GATE1 may be a gate high voltage, and the second gate voltage GATE2, the third gate voltage GATE3, and the fourth gate voltage GATE4 may be gate low voltages. In addition, in the first horizontal period H1, each of the first data voltage DATA1 and the second data voltage DATA2 may be a data voltage of a predetermined level for implementing a predetermined grayscale, and the third data voltage DATA3 may not be supplied with a data voltage.

Accordingly, in the first horizontal period H1, all of the switching transistors respectively connected to the plurality of first sub-pixels R arranged in the (6k-5)th column and the plurality of second sub-pixels G arranged in the (6k-4)th column in the odd-numbered rows are turned on.

Accordingly, in the first horizontal period H1, the first data voltage DATA1 may be charged into the plurality of first sub-pixels R arranged in the (6k-5)th column in the odd-numbered row odd, and the second data voltage DATA2 may be charged into the plurality of second sub-pixels G arranged in the (6k-4)th column in the odd-numbered row odd.

As illustrated in FIG. 5, in a second horizontal period H2, all of the first gate voltage GATE1 to the fourth gate voltage GATE4 may be gate low voltages. Accordingly, any switching transistor connected to any sub-pixel may be turned off.

As illustrated in FIG. 5, in a third horizontal period H3, the third gate voltage GATE3 may be a gate high voltage, and the second gate voltage GATE2, the first gate voltage GATE1, and the fourth gate voltage GATE4 may be gate low voltages. In addition, in the third horizontal period H3, each of the first data voltage DATA1 and the second data voltage DATA2 may be a data voltage of a predetermined level for implementing a predetermined grayscale, and the third data voltage DATA3 may not be supplied with a data voltage.

Accordingly, in the third horizontal period H3, all of the switching transistors respectively connected to the plurality of first sub-pixels R arranged in the (6k-5)th column and the plurality of second sub-pixels G arranged in the (6k-4)th column in the even-numbered row are turned on.

Accordingly, in the third horizontal period H3, the first data voltage DATA1 may be charged into the plurality of first sub-pixels R arranged in the (6k-5)th column of even-numbered row even, and the second data voltage DATA2 may be charged into the plurality of second sub-pixels G arranged in the (6k-4)th column of even-numbered row even.

As illustrated in FIG. 5, in a fourth horizontal period H4, all of the first gate voltage GATE1 to the fourth gate voltage GATE4 may be gate low voltages. Accordingly, any switching transistors connected to any sub-pixel may be turned off.

As described above, when the display device 100 according to an embodiment of the present disclosure displays a vertical pattern screen, the first data voltage DATA1 may have the same level during the first horizontal period H1 and the third horizontal period H3, and the second data voltage DATA2 may have the same level during the first horizontal period H1 and the third horizontal period H3.

Referring to FIGS. 3 and 6, the three data lines DATA1, DATA2, and DATA3 are present to respectively drive the sub-pixels R, G, and B of each of the four pixels PX arranged in the 2×2 matrix form. The two reference voltage lines RVL1 and RVL2 are used to compensate for the pixel.

As shown in (a) in FIG. 6, when the first gate voltage GATE1 at the turn-on level is applied via the first gate line GL1 while the data voltage is being supplied, the first gate signal is transmitted to the first sub-pixel R 611 disposed in the (6k-5)th column and the third sub-pixel B 616 disposed in the 6k-th column via the first gate line GL1, and the data voltage is charged into the first sub-pixel R 611 disposed in the (6k-5)th column and the third sub-pixel B 616 disposed in the 6k-th column, such that the first sub-pixel R 611 disposed in the (6k-5)th column and the third sub-pixel B 616 disposed in the 6k-th column emit light.

Thereafter, as shown in (b) in FIG. 6, the second gate signal is transmitted to the third sub-pixel B 623 disposed in the (6k-3)th column and the first sub-pixel R 624 disposed in the (6k-2)th column via the second gate line GL2, and the data voltage is charged to the third sub-pixel B 623 disposed in the (6k-3)th column and the first sub-pixel R 624 disposed in the (6k-2)th column, such that the third sub-pixel B 623 disposed in the (6k-3)th column and the first sub-pixel R 624 disposed in the (6k-2)th column emit light.

Thereafter, as shown in (c) in FIG. 6, the third gate signal is transmitted to the second sub-pixel G 632 disposed in the (6k-4)th column via the third gate line GL3, and the data voltage is charged into the second sub-pixel G 632 disposed in the (6k-4)th column, and thus the second sub-pixel G 632 disposed in the (6k-4)th column emits light.

Thereafter, as shown in (d) in FIG. 6, the fourth gate signal is transmitted to the second sub-pixel G 645 disposed in the (6k-1)th column via the fourth gate line GL4, and the data voltage is charged into the second sub-pixel G 645 disposed in the (6k-1)th column, and thus the second sub-pixel G 645 disposed in the (6k-1)th column emits light.

As described above, the three data lines DATA1, DATA2, and DATA3 are present to respectively drive the sub-pixels R, G, and B of each of the four pixels PX arranged in the form of a 2×2 matrix. The two reference voltage lines RVL1 and RVL2 can be used to compensate for the sub-pixels.

However, as the number of data lines and the number of reference voltage lines are not equal to each other, the sensing time to sense the sub-pixels R, G, and B of each of the four pixels PX arranged in a 2×2 matrix form increases.

Accordingly, there is a need for a display panel in which the number of data lines is equal to a multiple of the number of reference voltage lines to reduce the sensing time to sense the sub-pixels R, G, and B.

According to an embodiment of the present disclosure, the display panel 110 in which three data lines for respectively driving the sub-pixels R, G, and B of each of the four pixels PX arranged in a 2×2 matrix form, and three reference voltage lines for compensation for the sub-pixels R, G, and B are disposed, and the display device 100 including the same are provided.

Hereinafter, a scheme of shortening a time taken for sensing a pixel in each of a display panel in which one pixel has three sub-pixels and a display panel in which one pixel has four sub-pixels, thereby shortening a compensation time of the display panel will be described.

### A. Embodiment of Display Panel in Which Three Sub-Pixels are Disposed in One Pixel

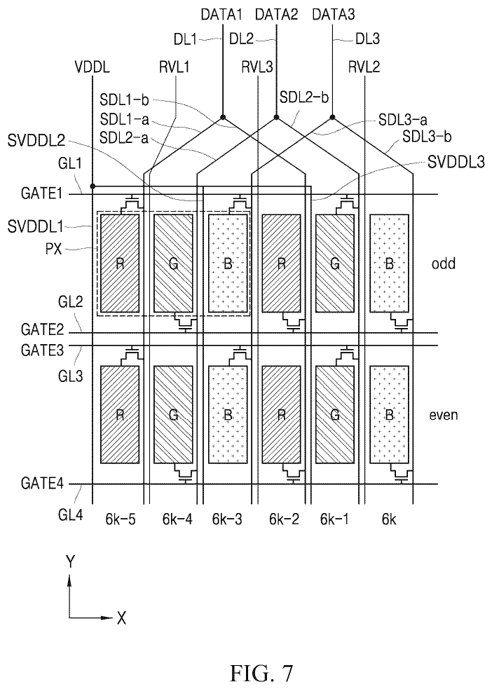

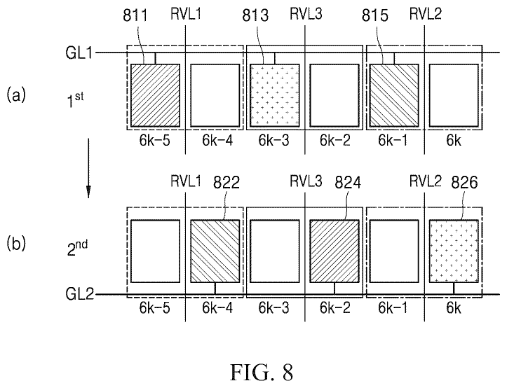

FIG. 7 is a first example diagram illustrating an arrangement relationship of sub-pixels when a pixel of a display panel according to an embodiment of the present disclosure has three sub-pixels. FIG. 8 is an example diagram illustrating a sensing sequence of a plurality of sub-pixels in FIG. 7.

For convenience of description, only four pixels PX arranged in a 2×2 matrix form are illustrated in FIG. 7. In an arrangement relationship of four pixels PX arranged in a 2×2 matrix form in the display area DA, the sub-pixels of the two pixels PX in the same row can be alternately arranged with each other in the row direction in a manner flipped relative to each other in a column direction. In addition, a transistor disposed between the adjacent sub-pixels R, G, and B and the data line means the switching transistor SWT described in FIG. 2.

According to an embodiment of the present disclosure, each of the plurality of data lines DL1, DL2, and DL3 can divide into a plurality of sub-data lines SDL1-a, SDL1-b, SDL2-a, SDL2-b, SDL3-a, and SDL3-b.

For example, the first data line DL1 can divide into a plurality of first sub-data lines SDL1-a and SDL1-b, and the second data line DL2 can divide into a plurality of second sub-data lines SDL2-a and SDL2-b. In addition, the third data line DL3 can divide into the plurality of third sub-data lines SDL3-a and SDL3-b.

According to an embodiment of the present disclosure, the first sub-data lines SDL1-a and SDL1-b can include a (1-a)th sub-data line SDL1-a and a (1-b)th sub-data line SDL1-b, and the second sub-data lines SDL2-a and SDL2-b can include a (2-a)th sub-data line SDL2-a and a (2-b)th sub-data line SDL2-b. The third sub-data lines SDL3-a and SDL3-b can include a (3-a)th sub-data line SDL3-a and a (3-b)th sub-data line SDL3-b.

According to an embodiment of the present disclosure, the high potential voltage line VDDL can divide into three sub-high potential voltage lines SVDDL1, SVDDL2, and SVDDL3, and each sub-high potential voltage line can be disposed between the adjacent sub-pixels.

For example, the first sub-high potential voltage line SVDDL1 can be disposed outside (e.g., on the left side of) the plurality of first sub-pixels R arranged in the (6k-5)th column, and the second sub-high potential voltage line SVDDL2 can be disposed between the plurality of second sub-pixels G arranged in the (6k-4)th column and the plurality of third sub-pixels B arranged in the (6k-3)th column. The third sub-high potential voltage line SVDDL3 can be disposed between the plurality of first sub-pixels R arranged in the (6k-2)th column and the plurality of second sub-pixels G arranged in the (6k-1)th column.

According to an embodiment of the present disclosure, one pixel PX can include the three sub-pixels R, G, and B. For example, as shown in FIG. 7, the pixel PX can include a first sub-pixel R, a second sub-pixel G, and a third sub-pixel B.

According to an embodiment of the present disclosure, the second sub-pixel G of the first pixel can be disposed at a position adjacent to the first sub-pixel R of the first pixel in the first direction (e.g., the x-axis direction). In addition, the third sub-pixel B of the first pixel can be disposed at a position adjacent to the second sub-pixel G of the first pixel in the first direction (e.g., the x-axis direction). The second sub-pixel G of the first pixel is disposed between the first sub-pixel R of the first pixel and the third sub-pixel B of the first pixel in the first direction. Here, the first sub-pixel R may be referred to as “a first line-sub-pixel”, and the second sub-pixel G may be referred to as “a second line-sub-pixel”. Alternatively, the second sub-pixel G may be referred to as “a first line-sub-pixel”, and the third sub-pixel B may be referred to as “a second line-sub-pixel”.

This arrangement of the sub-pixels SP is the same as described above with reference to FIG. 3.

For example, the plurality of first sub-pixels R can be arranged in each of the (6k-5)th column and the (6k-2)th column, and the plurality of second sub-pixels G can be arranged in each of the (6k-4)th column and the (6k-1)th column. In addition, the plurality of third sub-pixels B can be arranged in each of the (6k-3)th column and the 6k-th column. In this regard, k means a natural number greater than or equal to 1. The arrangement of the sub-pixels according to the present disclosure is not limited to FIG. 7. For example, the arrangement from the left to the right in the first direction (e.g., x-axis direction) of plurality of first sub-pixels R, the plurality of second sub-pixels G and the plurality of third sub-pixels B is not limited to R-G-B, and may be other arrangement such as R-B-G, G-R-B, or the like.

That is, the first sub-pixel R, the second sub-pixel G, and the third sub-pixel B can be sequentially and repeatedly arranged along one odd-numbered row or one even-numbered row.

According to an embodiment of the present disclosure, the sub-pixels of the first pixel and the second pixel disposed adjacent to each other in the first direction (e.g., the x-axis direction) can be alternately arranged with each other in the row direction in a manner flipped relative to each other in a column direction.

According to an embodiment of the present disclosure, the plurality of first sub-data lines SDL1-a and SDL1-b can be disposed adjacent to the plurality of first sub-pixels R so as to be connected to the plurality of first sub-pixels R.

Specifically, the (1-a)th sub-data line SDL1-a can be disposed between the plurality of first sub-pixels R arranged in the (6k-5)th column and the plurality of second sub-pixels G arranged in the (6k-4)th column, and can be electrically connected to the plurality of first sub-pixels R arranged in the (6k-5)th column. In addition, the (1-b)th sub-data lines SDL1-b can be disposed between the plurality of first sub-pixels R arranged in the (6k-2)th column and the plurality of second sub-pixels G arranged in the (6k-1)th column, and can be electrically connected to the plurality of first sub-pixels R arranged in the (6k-2)th column.

According to an embodiment of the present disclosure, the plurality of second sub-data lines SDL2-a and SDL2-b can be disposed adjacent to the plurality of second sub-pixels G and can be connected to the plurality of second sub-pixels G.

Specifically, the (2-a)th sub-data line SDL2-a can be disposed between the plurality of second sub-pixels G arranged in the (6k-4)th column and the plurality of third sub-pixels B arranged in the (6k-3)th column, and can be electrically connected to the plurality of second sub-pixels G arranged in the (6k-4)th column. In addition, the (2-b)th sub-data line SDL2-b can be disposed between the plurality of second sub-pixels G arranged in the (6k-1)th column and the plurality of third sub-pixels B arranged in the 6k-th column, and can be electrically connected to the plurality of second sub-pixels G arranged in the (6k-1)th column.

According to an embodiment of the present disclosure, the plurality of third sub-data lines SDL3-a and SDL3-b can be disposed adjacent to the plurality of third sub-pixels B so as to be connected to the plurality of third sub-pixels B.

Specifically, the (3-a)th sub-data line SDL3-a can be disposed between the plurality of third sub-pixels B arranged in the (6k-3)th column and the plurality of first sub-pixels R arranged in the (6k-2)th column, and can be electrically connected to the plurality of third sub-pixels B arranged in the (6k-3)th column. In addition, the (3-b)th sub-data line SDL3-b can be electrically connected to the plurality of third sub-pixels B arranged in the 6k-th column.

According to an embodiment of the present disclosure, a first data voltage DATA1 as a red data voltage can be applied to the first data line DL1, and a second data voltage DATA2 as a green data voltage can be applied to the second data line DL2. In addition, a third data voltage DATA3 as a blue data voltage can be applied to the third data line DL3.

Accordingly, the first data voltage DATA1 as a red data voltage can also be applied to the plurality of first sub-data lines SDL1-a and SDL1-b, and the second data voltage DATA2 as a green data voltage can also be applied to the plurality of second sub-data lines SDL2-a and SDL2-b. In addition, the third data voltage DATA3 as a blue data voltage can also be applied to the plurality of third sub-data lines SDL3-a and SDL3-b.

According to an embodiment of the present disclosure, each of the plurality of gate lines GL1 to GL4 can be disposed on each of both opposing sides in the column direction (e.g., upper and lower sides in the drawing) of each of the first and second rows of the plurality of sub-pixels R, G, and B. The two gate lines GL2 and GL3 can be disposed between the first and second rows of the plurality of sub-pixels R, G, and B.

Specifically, referring to FIG. 7, the first gate line GL1 and the second gate line GL2 can be respectively disposed on both opposing sides in the column direction (e.g., upper and lower sides in the drawing) of the plurality of sub-pixels R, G, and B of the odd-numbered row, and the third gate line GL3 and the fourth gate line GL4 can be respectively disposed on both opposing sides in the column direction (e.g., upper and lower sides in the drawing) of the plurality of sub-pixels R, G, and B of the even-numbered row. Accordingly, the second gate line GL2 and the third gate line GL3 can be disposed between the plurality of sub-pixels R, G, and B of the odd-numbered row and the plurality of sub-pixels R, G, and B of the even-numbered row.

In one example, the plurality of pixels PX can be connected to different gate lines GL1 to GL4.

Specifically, the sub-pixels R and B respectively disposed in the (6k-5)th column and the (6k-3)th column of the odd-numbered row odd can be connected to the first gate line GL1, and the sub-pixel G disposed in the (6k-4)th column of the odd-numbered row odd can be connected to the second gate line GL2. In addition, the sub-pixels R and B respectively disposed in the (6k-2)th column and the 6k-th column of the odd-numbered row odd can be connected to the second gate line GL2, and the sub-pixel G disposed in the (6k-1)th column of the odd-numbered row odd can be connected to the first gate line GL1. As described above, the sub-pixels of the pixels PX of the display panel 110 according to the present disclosure can be alternately arranged with each other in the row direction in a manner flipped relative to each other in a column direction.

In addition, the sub-pixels R and B respectively disposed in the (6k-5)th column and the (6k-3)th column of the even-numbered row even can be connected to the third gate line GL3. The sub-pixel G disposed in the (6k-4)th column of the even-numbered row even can be connected to the fourth gate line GL4. In addition, the sub-pixels R and B respectively disposed in the (6k-2)th column and the 6k-th column of the even-numbered row even can be connected to the fourth gate line GL4. the sub-pixel G disposed in the (6k-1)th column of the even-numbered row even can be connected to the third gate line GL3.

According to an embodiment of the present disclosure, each of the plurality of reference voltage lines RVL1, RVL2, and RVL3 can be disposed inside one pixel PX or can be disposed between the adjacent pixels PX.

For example, the first reference voltage line RVL1 can be disposed between the plurality of first sub-pixels R arranged in the (6k-5)th column and the plurality of second sub-pixels G arranged in the (6k-4)th column and can apply the reference voltage Vref to the source electrodes of the driving transistors DT of the first sub-pixels R of the first pixel and the second sub-pixels G of the first pixel. In addition, the second reference voltage line RVL2 can be disposed between the plurality of second sub-pixels G arranged in the (6k-1)th column and the plurality of third sub-pixels B arranged in the 6k-th column and can apply the reference voltage Vref to the source electrodes of the driving transistors DT of the second sub-pixels G of the second pixel and the third sub-pixels B of the second pixel.

In addition, the third reference voltage line RVL3 can be disposed between the plurality of third sub-pixels B arranged in the (6k-3)th column and the plurality of first sub-pixels R arranged in the (6k-2)th column and can apply the reference voltage Vref to the source electrodes of the driving transistors DT of the third sub-pixels B of the first pixel and the first sub-pixels R of the second pixel.

According to an embodiment of the present disclosure, each of the reference voltage lines RVL1, RVL2, and RVL3 disposed in the display panel 110 of the present disclosure can be disposed every two sub-pixels. For example, the first reference voltage line RVL1 can be disposed between the first sub-pixel and the second sub-pixel, the second reference voltage line RVL2 can be disposed between the third sub-pixel and the fourth sub-pixel, and the third reference voltage line RVL3 can be disposed between the fifth sub-pixel and the sixth sub-pixel.

As described above, when each pixel PX includes the three sub-pixels, the three reference voltage lines can be disposed in the two pixels PX.

According to an embodiment of the present disclosure, the high potential voltage line VDDL can be disposed on one side of the first pixel (e.g., on one side of the sub-pixel R disposed in the (6k-5)th column). For example, the reference voltage line RVL can include a first reference voltage line RVL1, a second reference voltage line RVL2, and a third reference voltage line RVL3.

According to an embodiment of the present disclosure, the first reference voltage line RVL1 can be disposed between the plurality of first sub-pixels R arranged in the (6k-5)th column and the plurality of second sub-pixels G arranged in the (6k-4)th column. The second reference voltage line RVL2 can be disposed on one side (e.g., the left side) of the plurality of third sub-pixels B arranged in the 6k-th column for example, disposed between the plurality of third sub-pixels B arranged in the 6k-th column and the plurality of second sub-pixels G arranged in the (6k-1)th column. In addition, the third reference voltage line RVL3 can be disposed between the plurality of third sub-pixels B arranged in the (6k-3)th column and the plurality of first sub-pixels R arranged in the (6k-2)th column.

Hereinafter, a sensing sequence of a plurality of sub-pixels according to an embodiment of the present disclosure will be described with reference to FIGS. 7 and 8.

According to an embodiment of the present disclosure, the first gate voltage GATE1 is output via the first gate line GL1, and the second gate voltage GATE2 is output via the second gate line GL2.

In addition, the first data voltage DATA1 is output via the first data line DL1, the second data voltage DATA2 is output via the second data line DL2, and the third data voltage DATA3 is output via the third data line DL3.

Referring to FIGS. 7 and 8, the three data lines DATA1, DATA2, and DATA3 are present to respectively drive the sub-pixels R, G, and B of each of the two pixels PX, and the three reference voltage lines RVL1, RVL2, and RVL3 are used to compensate for the sub-pixels.

As shown in (a) in FIG. 8, when the first gate voltage GATE1 at the turn-on level is applied via the first gate line GL1 while the data voltage is being supplied, the first gate signal can be transmitted to the first sub-pixel R 811 disposed in the (6k-5)th column, the third sub-pixel B 813 disposed in the (6k-3)th column, and the second sub-pixel G 815 disposed in the (6k-1)th column via the first gate line GL1. In addition, the data voltage is charged into the first sub-pixel R 811 disposed in the (6k-5)th column, the third sub-pixel B 813 disposed in the (6k-3)th column, and the second sub-pixel G 815 disposed in the (6k-1)th column, and thus the first sub-pixel R 811 disposed in the (6k-5)th column, the third sub-pixel B 813 disposed in the (6k-3)th column, and the second sub-pixel G 815 disposed in the (6k-1)th column emit light.

Referring to FIG. 4, in the first horizontal period H1, the first gate voltage GATE1 is a gate high voltage, and the second gate voltage GATE2, the third gate voltage GATE3, and the fourth gate voltage GATE4 are gate low voltages. During the first horizontal period H1, all of the switching transistors respectively connected to the first sub-pixel R 811 disposed in the (6k-5)th column, the third sub-pixel B 813 disposed in the (6k-3)th column, and the second sub-pixel G 815 disposed in the (6k-1)th column in the odd-numbered row are turned on.

As shown in (b) in FIG. 8, when the second gate voltage GATE2 at the turn-on level is applied via the second gate line GL2 while the data voltage is being supplied, the second gate signal can be transmitted to the second sub-pixel G 822 disposed in the (6k-4)th column, the first sub-pixel R 824 disposed in the (6k-2)th column, and the third sub-pixel B 826 disposed in the 6k-th column via the second gate line GL2. In addition, the second sub-pixel G 822 disposed in the (6k-4)th column, the first sub-pixel R 824 disposed in the (6k-2)th column, and the third sub-pixel B 826 disposed in the 6k-th column are charged with the data voltage, and thus the second sub-pixel G 822 disposed in the (6k-4)th column, the first sub-pixel R 824 disposed in the (6k-2)th column, and the third sub-pixel B 826 disposed in the 6k-th column emit light.

Referring to FIG. 4, in the second horizontal period H2, the second gate voltage GATE2 is a gate high voltage, and the first gate voltage GATE1, the third gate voltage GATE3, and the fourth gate voltage GATE4 are gate low voltages. During the second horizontal period H1, all of the switching transistors respectively connected to the second sub-pixel G 822 disposed in the (6k-4)th column, the first sub-pixel R 824 disposed in the (6k-2)th column, and the third sub-pixel B 826 disposed in the 6k-th column in the even-numbered row even are turned on.

As illustrated in FIGS. 7 and 8, the number of data lines DL is equal to a multiple of the number of reference voltage lines RL, such that the sensing time taken for sensing the sub-pixels R, G, and B can be reduced. For example, the display panel 110 according to the present disclosure in which the number of data lines DL is equal to a multiple of the number of reference voltage lines RL can reduce the sensing time taken for sensing the sub-pixels R, G, and B by 50%.

The display panel 110 according to an embodiment of the present disclosure can include a first pixel including three sub-pixels, a second pixel disposed at a position adjacent to the first pixel and including a plurality of sub-pixels, a first reference voltage line RVL1 supplying a reference voltage to at least one sub-pixel of the first pixel, a second reference voltage line RVL2 supplying a reference voltage to at least one sub-pixel of the second pixel, and a third reference voltage line RVL3 disposed between the first pixel and the second pixel.

According to an embodiment of the present disclosure, the third reference voltage line RVL3 can supply the reference voltage to each of a sub-pixel to which the reference voltage is not supplied via the first reference voltage line RVL1 among the plurality of sub-pixels of the first pixel and a sub-pixel to which the reference voltage is not supplied via the second reference voltage line RVL2 among the plurality of sub-pixels of the second pixel.

According to an embodiment of the present disclosure, the first reference voltage line can be disposed between a first sub-pixel of a first pixel and a second sub-pixel thereof adjacent to the first sub-pixel so as to supply a reference voltage to each of the first sub-pixel of the first pixel and the second sub-pixel thereof adjacent to the first sub-pixel.

According to an embodiment of the present disclosure, the second reference voltage line can be disposed between the second sub-pixel of the second pixel and a third sub-pixel thereof adjacent to the second sub-pixel so as to supply a reference voltage to the second sub-pixel of the second pixel and the third sub-pixel thereof adjacent to the second sub-pixel.

According to an embodiment of the present disclosure, the third reference voltage line can be disposed between the third sub-pixel of the first pixel and the first sub-pixel of the second pixel so as to supply a reference voltage to each of the third sub-pixel of the first pixel and the first sub-pixel of the second pixel.

According to an embodiment of the present disclosure, the driving circuit can be disposed on one or the other of both opposing sides in the column direction of the light-emission area of each of the plurality of sub-pixels of the first pixel and each of the plurality of sub-pixels of the second pixel, and the sub-pixels of the first pixel and the second pixel are alternately arranged with each other in the row direction in a manner flipped relative to each other in the column direction.

According to an embodiment of the present disclosure, the driving circuit can be disposed on one of both opposing sides in the column direction of a light-emission area of each of the first sub-pixel in the first pixel and the third sub-pixel in the first pixel, and the driving circuit can be disposed on the other of both opposing sides in the column direction of a light-emission area of the second sub-pixel in the first pixel.

According to an embodiment of the present disclosure, a driving circuit can be disposed on the other of both opposing sides in the column direction of a light-emission area of each of the first sub-pixel in the second pixel and the third sub-pixel in the second pixel, and the driving circuit can be disposed on one of both opposing sides in the column direction of a light-emission area of the second sub-pixel in the second pixel.

According to an embodiment of the present disclosure, the display panel can further include a plurality of gate lines for supplying a gate signal to the first pixel and the second pixel, and a gate signal applied via the first gate line among the plurality of gate lines can be supplied to the driving circuit of each of the first sub-pixel of the first pixel, the third sub-pixel of the first pixel, and the second sub-pixel of the second pixel to operate the first sub-pixel of the first pixel, the third sub-pixel of the first pixel, and the second sub-pixel of the second pixel.

According to an embodiment of the present disclosure, the gate signal applied via the second gate line among the plurality of gate lines can be supplied to the driving circuit of each of the second sub-pixel of the first pixel, the first sub-pixel of the second pixel, and the third sub-pixel of the second pixel to operate the second sub-pixel of the first pixel, the first sub-pixel of the second pixel, and the third sub-pixel of the second pixel.

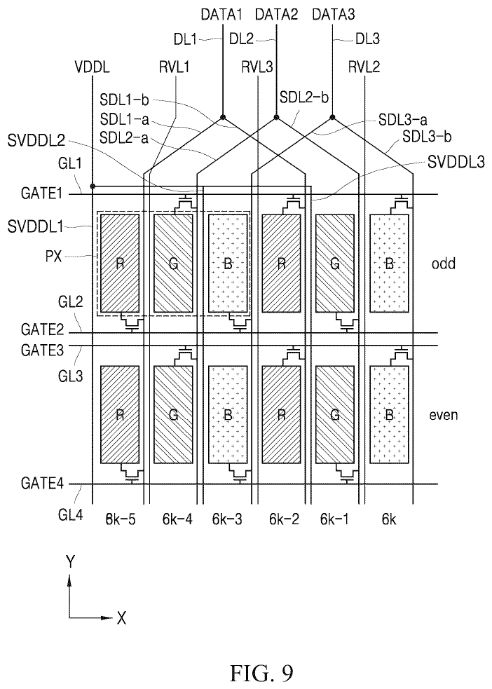

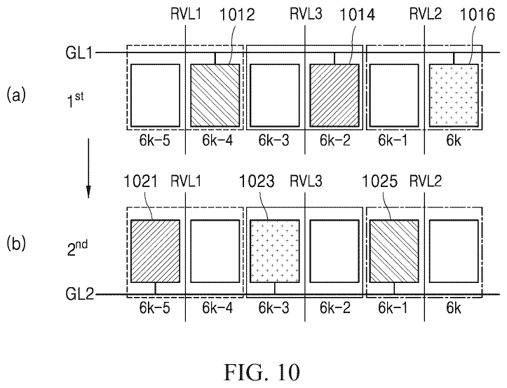

FIG. 9 is a second example diagram illustrating an arrangement relationship of sub-pixels when a pixel of a display panel according to an embodiment of the present disclosure has three sub-pixels. FIG. 10 is an example diagram illustrating a sensing sequence of a plurality of sub-pixels in FIG. 9.

For convenience of description, only four pixels PX arranged in a 2×2 matrix form are illustrated in FIG. 9. In an arrangement relationship of four pixels PX arranged in a 2×2 matrix form in the display area DA, the sub-pixels of the two pixels PX in the same row can be alternately arranged with each other in the row direction in a manner flipped relative to each other in a column direction. In addition, a transistor disposed between the adjacent sub-pixels R, G, and B and the data line means the switching transistor SWT described in FIG. 2.

According to an embodiment of the present disclosure, each of the plurality of data lines DL1, DL2, and DL3 can divide into a plurality of sub-data lines SDL1-a, SDL1-b, SDL2-a, SDL2-b, SDL3-a, and SDL3-b.

For example, the first data line DL1 can divide into a plurality of first sub-data lines SDL1-a and SDL1-b, and the second data line DL2 can divide into a plurality of second sub-data lines SDL2-a and SDL2-b. In addition, the third data line DL3 can divide into the plurality of third sub-data lines SDL3-a and SDL3-b.

According to an embodiment of the present disclosure, the first sub-data lines SDL1-a and SDL1-b can include a (1-a)th sub-data line SDL1-a and a (1-b)th sub-data line SDL1-b, and the second sub-data lines SDL2-a and SDL2-b can include a (2-a)th sub-data line SDL2-a and a (2-b)th sub-data line SDL2-b. The third sub-data lines SDL3-a and SDL3-b can include a (3-a)th sub-data line SDL3-a and a (3-b)th sub-data line SDL3-b.

According to an embodiment of the present disclosure, the high potential voltage line VDDL can divide into three sub-high potential voltage lines SVDDL1, SVDDL2, and SVDDL3, and each sub-high potential voltage line can be disposed between the adjacent sub-pixels.

For example, the first sub-high potential voltage line SVDDL1 can be disposed outside (e.g., on the left side of) the plurality of first sub-pixels R arranged in the (6k-5)th column, and the second sub-high potential voltage line SVDDL2 can be disposed between the plurality of second sub-pixels G arranged in the (6k-4)th column and the plurality of third sub-pixels B arranged in the (6k-3)th column. In addition, the third sub-high potential voltage line SVDDL3 can be disposed between the plurality of first sub-pixels R arranged in the (6k-2)th column and the plurality of second sub-pixels G arranged in the (6k-1)th column.

According to an embodiment of the present disclosure, one pixel PX can include three sub-pixels R, G, and B. For example, as shown in FIG. 9, the pixel PX can include a first sub-pixel R, a second sub-pixel G, and a third sub-pixel B. Here, the first sub-pixel R may be referred to as “a first line-sub-pixel”, and the second sub-pixel G may be referred to as “a second line-sub-pixel”. Alternatively, the second sub-pixel G may be referred to as “a first line-sub-pixel”, and the third sub-pixel B may be referred to as “a second line-sub-pixel”.

According to an embodiment of the present disclosure, the second sub-pixel G of the first pixel can be disposed at a position adjacent to the first sub-pixel R of the first pixel in the first direction (e.g., the x-axis direction). In addition, the third sub-pixel B of the first pixel can be disposed at a position adjacent to the second sub-pixel G of the first pixel in the first direction (e.g., the x-axis direction).

The arrangement of the sub-pixels SP is the same as described above with reference to FIG. 3.

For example, the plurality of first sub-pixels R can be arranged in each of the (6k-5)th column and the (6k-2)th column, and the plurality of second sub-pixels G can be arranged in each of the (6k-4)th column and the (6k-1)th column. In addition, the plurality of third sub-pixels B can be arranged in each of the (6k-3)th column and the 6k-th column. In this regard, k means a natural number greater than or equal to 1. The arrangement of the sub-pixels according to the present disclosure is not limited to FIG. 9.

That is, the first sub-pixel R, the second sub-pixel G, and the third sub-pixel B can be sequentially and repeatedly arranged along one odd-numbered row or one even-numbered row.

According to an embodiment of the present disclosure, the sub-pixels of the first pixel and the second pixel disposed adjacent to each other in the first direction (e.g., the x-axis direction) of the first pixel can be alternately arranged with each other in the row direction in a manner flipped relative to each other in a column direction.

According to an embodiment of the present disclosure, the plurality of first sub-data lines SDL1-a and SDL1-b can be disposed adjacent to the plurality of first sub-pixels R so as to be connected to the plurality of first sub-pixels R.

Specifically, the (1-a)th sub-data line SDL1-a can be disposed between the plurality of first sub-pixels R arranged in the (6k-5)th column and the plurality of second sub-pixels G arranged in the (6k-4)th column, and can be electrically connected to the plurality of first sub-pixels R arranged in the (6k-5)th column. In addition, the plurality of (1-b)th sub-data lines SDL1-b can be disposed between the plurality of first sub-pixels R arranged in the (6k-2)th column and the plurality of second sub-pixels G arranged in the (6k-1)th column, and can be electrically connected to the plurality of first sub-pixels R arranged in the (6k-2)th column.

According to an embodiment of the present disclosure, the plurality of second sub-data lines SDL2-a and SDL2-b can be disposed adjacent to the plurality of second sub-pixels G and can be connected to the plurality of second sub-pixels G.

Specifically, the (2-a)th sub-data line SDL2-a can be disposed between the plurality of second sub-pixels G arranged in the (6k-4)th column and the plurality of third sub-pixels B arranged in the (6k-3)th column, and can be electrically connected to the plurality of second sub-pixels G arranged in the (6k-4)th column. In addition, the (2-b)th sub-data line SDL2-b can be disposed between the plurality of second sub-pixels G arranged in the (6k-1)th column and the plurality of third sub-pixels B arranged in the 6k-th column, and can be electrically connected to the plurality of second sub-pixels G arranged in the (6k-1)th column.

According to an embodiment of the present disclosure, the plurality of third sub-data lines SDL3-a and SDL3-b can be disposed adjacent to the plurality of third sub-pixels B and can be connected to the plurality of third sub-pixels B.

Specifically, the (3-a)th sub-data line SDL3-a can be disposed between the plurality of third sub-pixels B arranged in the (6k-3)th column and the plurality of first sub-pixels R arranged in the (6k-2)th column, and can be electrically connected to the plurality of third sub-pixels B arranged in the (6k-3)th column. In addition, the (3-b)th sub-data line SDL3-b can be electrically connected to the plurality of third sub-pixels B arranged in the 6k-th column.

According to an embodiment of the present disclosure, a first data voltage DATA1 as a red data voltage can be applied to the first data line DL1, and a second data voltage DATA2 as a green data voltage can be applied to the second data line DL2. In addition, a third data voltage DATA3 as a blue data voltage can be applied to the third data line DL3.

Accordingly, the first data voltage DATA1 as a red data voltage can be applied to the plurality of first sub-data lines SDL1-a and SDL1-b, and the second data voltage DATA2 as a green data voltage can be applied to the plurality of second sub-data lines SDL2-a and SDL2-b. In addition, the third data voltage DATA3 as a blue data voltage can also be applied to the plurality of third sub-data lines SDL3-a and SDL3-b.

According to an embodiment of the present disclosure, each of the plurality of gate lines GL1 to GL4 can be respectively disposed on each of both opposing sides in the column direction (e.g., upper and lower sides in the drawing) of each of the first and second rows of the plurality of sub-pixels R, G, and B. The two gate lines GL2 and GL3 can be disposed between the first and second rows of the plurality of sub-pixels R, G, and B.

Specifically, referring to FIG. 9, the first gate line GL1 and the second gate line GL2 can be respectively disposed on both opposing sides in the column direction (e.g., upper and lower sides in the drawing) of the plurality of sub-pixels R, G, and B of the odd-numbered row. The third gate line GL3 and the fourth gate line GL4 can be respectively disposed on both opposing sides in the column direction (e.g., upper and lower sides in the drawing) of the plurality of sub-pixels R, G, and B of the even-numbered row. Accordingly, the second gate line GL2 and the third gate line GL3 can be disposed between the plurality of sub-pixels R, G, and B of the odd-numbered row and the plurality of sub-pixels R, G, and B of the even-numbered row.

In one example, the plurality of pixels PX can be connected to different gate lines GL1 to GL4.

Specifically, referring to FIG. 9, the sub-pixel G disposed in the (6k-4)th column of the odd-numbered row odd can be connected to the first gate line GL1. The sub-pixel R disposed in the (6k-5)th column of the odd-numbered row odd and the sub-pixel B disposed in the (6k-3)th column of the odd-numbered row odd can be connected to the second gate line GL2. In addition, the sub-pixels R and B respectively disposed in the (6k-2)th column and the 6k-th column of the odd-numbered row odd can be connected to the first gate line GL1. The sub-pixel G disposed in the (6k-1)th column of the odd-numbered row odd can be connected to the second gate line GL2. As described above, the sub-pixels of the pixels of the display panel 110 according to the present disclosure can be alternately arranged with each other in the row direction in a manner flipped relative to each other in a column direction.

In addition, the sub-pixel G arranged in the (6k-4)th column of the even-numbered row even can be connected to the third gate line GL3, and the sub-pixel R disposed in the (6k-5)th column, and the sub-pixel B disposed in the (6k-3)th column of the even-numbered row even can be connected to the fourth gate line GL4. In addition, the sub-pixels R and B respectively disposed in the (6k-2)th column and the 6k-th column of the even-numbered row even can be connected to the third gate line GL3. The sub-pixel G arranged in the (6k-1)th column of the even-numbered row even can be connected to the fourth gate line GL4.

According to an embodiment of the present disclosure, each of the plurality of reference voltage lines RVL1, RVL2, and RVL3 can be disposed inside one pixel PX or can be disposed between the adjacent pixels PX.

For example, the first reference voltage line RVL1 can be disposed between the plurality of first sub-pixels R arranged in the (6k-5)th column and the plurality of second sub-pixels G arranged in the (6k-4)th column and can apply the reference voltage Vref to the source electrodes of the driving transistors DT of the first sub-pixels R of the first pixel and the second sub-pixels G of the first pixel. In addition, the second reference voltage line RVL2 can be disposed between the plurality of second sub-pixels G arranged in the (6k-1)th column and the plurality of third sub-pixels B arranged in the 6k-th column and can apply the reference voltage Vref to the source electrodes of the driving transistors DT of the second sub-pixels G of the second pixel and the third sub-pixels B of the second pixel.

In addition, the third reference voltage line RVL3 can be disposed between the plurality of third sub-pixels B arranged in the (6k-3)th column and the plurality of first sub-pixels R arranged in the (6k-2)th column and can apply the reference voltage Vref to the source electrodes of the driving transistors DT of the third sub-pixels B of the first pixel and the first sub-pixels R of the second pixel.

According to an embodiment of the present disclosure, each of the reference voltage lines RVL1, RVL2, and RVL3 disposed in the display panel 110 of the present disclosure can be disposed every two sub-pixels.

According to an embodiment of the present disclosure, the high-potential voltage line VDDL can be disposed on one side (e.g., the left side) of the first pixel and can divide into three sub-high-potential voltage lines SVDDL1, SVDDL2, and SVDDL3, and each sub-high-potential voltage line can be disposed between adjacent ones of the plurality of pixels PX.

According to an embodiment of the present disclosure, the first reference voltage line RVL1 can be disposed between the plurality of first sub-pixels R arranged in the (6k-5)th column and the plurality of second sub-pixels G arranged in the (6k-4)th column. The second reference voltage line RVL2 can be disposed on one side (e.g., the left side) of the plurality of third sub-pixels B arranged in the 6k-th column, for example, disposed between the plurality of third sub-pixels B arranged in the 6k-th column and the plurality of second sub-pixels G arranged in the (6k-1)th column. In addition, the third reference voltage line RVL3 can be disposed between the plurality of third sub-pixels B arranged in the (6k-3)th column and the plurality of first sub-pixels R arranged in the (6k-2)th column.

Hereinafter, a sensing sequence of a plurality of sub-pixels according to an embodiment of the present disclosure will be described with reference to FIGS. 9 and 10.

According to an embodiment of the present disclosure, the first gate voltage GATE1 is output via the first gate line GL1, and the second gate voltage GATE2 is output via the second gate line GL2.

In addition, the first data voltage DATA1 is output via the first data line DL1, the second data voltage DATA2 is output via the second data line DL2, and the third data voltage DATA3 is output via the third data line DL3.

Referring to FIGS. 9 and 10, three data lines DATA1, DATA2, and DATA3 are present to respectively drive the sub-pixels R, G, and B of each of two pixels PX, and three reference voltage lines RVL1, RVL2, and RVL3 are used to compensate for the sub-pixels.

As shown in (a) of FIG. 10, when the first gate voltage GATE1 at the turn-on level is applied via the first gate line GL1 while the data voltage is being supplied, the first gate signal can be transmitted to the second sub-pixel G 1012 disposed in the (6k-4)th column, the first sub-pixel R 1014 disposed in the (6k-2)th column, and the third sub-pixel B 1016 disposed in the 6k-th column via the first gate line GL1. The data voltage is charged into the second sub-pixel G 1012 disposed in the (6k-4)th column, the first sub-pixel R 1014 disposed in the (6k-2)th column, and the third sub-pixel B 1016 disposed in the 6k-th column, and thus the second sub-pixel G 1012 disposed in the (6k-4)th column, the first sub-pixel R 1014 disposed in the (6k-2)th column, and the third sub-pixel B 1016 disposed in the 6k-th column emit light.

Referring to FIG. 4, in the first horizontal period H1, the first gate voltage GATE1 is a gate high voltage, and the second gate voltage GATE2, the third gate voltage GATE3, and the fourth gate voltage GATE4 are gate low voltages. During the first horizontal period H1, all of the switching transistors respectively connected to the second sub-pixel G 1012 disposed in the (6k-4)th column, the first sub-pixel R 1014 disposed in the (6k-2)th column, and the third sub-pixel B 1016 disposed in the 6kth column in the odd-numbered row odd are turned on.

As shown in (b) in FIG. 10, when the second gate voltage GATE2 at the turn-on level is applied via the second gate line GL2 while the data voltage is being supplied, the second gate signal can be transmitted to the first sub-pixel R 1021 disposed in the (6k-5)th column, the third sub-pixel B 1023 disposed in the (6k-3)th column, and the second sub-pixel G 1025 disposed in the (6k-1)th column via the second gate line GL2. The data voltage is charged into the first sub-pixel R 1021 disposed in the (6k-5)th column, the third sub-pixel B 1023 disposed in the (6k-3)th column, and the second sub-pixel G 1025 disposed in the (6k-1)th column, and thus the first sub-pixel R 1021 disposed in the (6k-5)th column, the third sub-pixel B 1023 disposed in the (6k-3)th column, and the second sub-pixel G 1025 disposed in the (6k-1)th column emit light.

Referring to FIG. 4, in the second horizontal period H2, the second gate voltage GATE2 is a gate high voltage, and the first gate voltage GATE1, the third gate voltage GATE3, and the fourth gate voltage GATE4 are gate low voltages. During the second horizontal period H2, all of the switching transistors respectively connected to the first sub-pixel R 1021 disposed in the (6k-5)th column, the third sub-pixel B 1023 disposed in the (6k-3)th column, and the second sub-pixel G 1025 disposed in the (6k-1)th column in the even-numbered row even are turned on.

As illustrated in FIGS. 9 and 10, the number of data lines DL is equal to a multiple of the number of reference voltage lines RL, such that the sensing time taken for sensing the sub-pixels R, G, and B can be reduced. For example, the display panel 110 according to the present disclosure in which the number of data lines DL is equal to a multiple of the number of reference voltage lines RL can reduce the sensing time taken for sensing the sub-pixels R, G, and B by 50%.

The display panel 110 according to an embodiment of the present disclosure can include a first pixel including a plurality of sub-pixels, a second pixel disposed at a position adjacent to the first pixel and including a plurality of sub-pixels, a first reference voltage line RVL1 supplying a reference voltage to at least one sub-pixel of the first pixel, a second reference voltage line RVL2 supplying a reference voltage to at least one sub-pixel of the second pixel, and a third reference voltage line RVL3 disposed between the first pixel and the second pixel.

According to an embodiment of the present disclosure, the third reference voltage line RVL3 can supply the reference voltage to each of a sub-pixel to which the reference voltage is not supplied via the first reference voltage line RVL1 among the plurality of sub-pixels of the first pixel and a sub-pixel to which the reference voltage is not supplied via the second reference voltage line RVL2 among the plurality of sub-pixels of the second pixel.

According to an embodiment of the present disclosure, the third reference voltage line RVL3 can supply a reference voltage to each of the third sub-pixel of the first pixel and the first sub-pixel of the second pixel.

According to an embodiment of the present disclosure, the first reference voltage line RVL1 can be disposed between the first sub-pixel of the first pixel and the second sub-pixel thereof adjacent to the first sub-pixel.

According to an embodiment of the present disclosure, the second reference voltage line RVL2 can be disposed between the second sub-pixel of the second pixel and the third sub-pixel thereof adjacent to the second sub-pixel.

According to an embodiment of the present disclosure, the third reference voltage line RVL3 can be disposed between the third sub-pixel of the first pixel and the first sub-pixel of the second pixel.

According to an embodiment of the present disclosure, the driving circuit can be disposed on one or the other of both opposing sides in the column direction of the light-emission area of each of the plurality of sub-pixels of the first pixel and each of the plurality of sub-pixels of the second pixel, and the sub-pixels of the first pixel and the second pixel are alternately arranged with each other in the row direction in a manner flipped relative to each other in the column direction.

According to an embodiment of the present disclosure, the driving circuit can be disposed on one of both opposing sides in the column direction of the light-emission area of the second sub-pixel in the first pixel, and the driving circuit can be disposed on the other of both opposing sides in the column direction of the light-emission area of each of the first sub-pixel in the first pixel and the third sub-pixel in the first pixel.

According to an embodiment of the present disclosure, the driving circuit can be disposed on one of both opposing sides in the column direction of a light-emission area of each of the first sub-pixel in the second pixel and the third sub-pixel in the second pixel, and the driving circuit can be disposed on the other of both opposing sides in the column direction of the light-emission area of the second sub-pixel in the second pixel.

According to an embodiment of the present disclosure, the display panel of the present disclosure can further include a plurality of gate lines for supplying a gate signal to the first pixel and the second pixel, and a gate signal applied via the first gate line among the plurality of gate lines can be supplied to the driving circuit of each of the second sub-pixel of the first pixel, the first sub-pixel of the second pixel, and the third sub-pixel of the second pixel to operate the second sub-pixel of the first pixel, the first sub-pixel of the second pixel, and the third sub-pixel of the second pixel.

According to an embodiment of the present disclosure, the gate signal applied via the second gate line among the plurality of gate lines can be supplied to the driving circuit of each of the first sub-pixel of the first pixel, the third sub-pixel of the first pixel, and the second sub-pixel of the second pixel, thereby operating the first sub-pixel of the first pixel, the third sub-pixel of the first pixel, and the second sub-pixel of the second pixel.

According to an embodiment of the present disclosure, a high-potential voltage line can apply a high-potential voltage to the driving circuit of each of the plurality of sub-pixels of the first pixel and the driving circuit of each of the plurality of sub-pixels of the second pixel. The high-potential voltage line divides into three sub-high-potential voltage lines.

According to an embodiment of the present disclosure, among the three sub-high potential voltage lines, the first sub-high potential voltage line can be disposed on one side of the first sub-pixel of the first pixel.

According to an embodiment of the present disclosure, among the three sub-high potential voltage lines, a second sub-high potential voltage line can be disposed between the second sub-pixel of the first pixel and the third sub-pixel of the first pixel.

According to an embodiment of the present disclosure, among the three sub-high potential voltage lines, a third sub-high potential voltage line can be disposed between the first sub-pixel of the second pixel and the second sub-pixel of the second pixel.

According to the present disclosure, the description of the example in which the three sub-pixels R, G, and B are included in one pixel can be applied to an example in which four sub-pixels R, W, G, and B is disposed in one pixel. Thus, the display panel according to the present disclosure is not limited thereto.

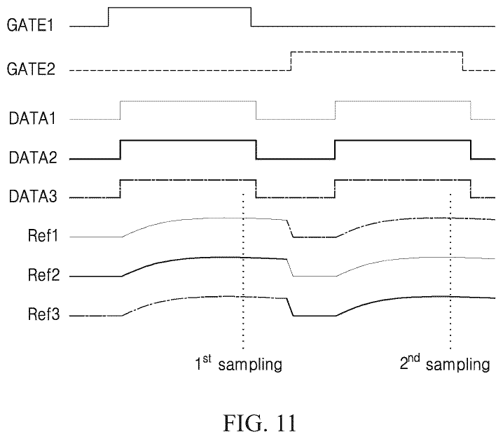

FIG. 11 is a timing diagram of a gate voltage, a data voltage, and a voltage charged into a storage capacitor according to an embodiment of the present disclosure.

Referring to (a) of FIG. 8 and FIG. 11, when the first gate voltage GATE1 is the gate high voltage, during the horizontal period, all of the switching transistors respectively connected to the plurality of first sub-pixels R arranged in the (6k-5)th column, the plurality of third sub-pixels B arranged in the (6k-3)th column, and the plurality of second sub-pixels G arranged in the (6k-1)th column in the odd-numbered row are turned on.

Further, referring to (b) in FIG. 8 and FIG. 11, when the second gate voltage GATE2 is the gate high voltage, during the horizontal period, all of the switching transistors respectively connected to the plurality of second sub-pixels G arranged in the (6k-4)th column, the plurality of first sub-pixels R arranged in the (6k-2)th column, and the plurality of third sub-pixels B arranged in the 6k-th column in the odd-numbered row are turned on.

Referring to FIG. 2, the voltage V2 of the second node N2 of the driving transistor DT can be initialized with the reference voltage Vref for sensing operation. The second node N2 of the driving transistor DT can be in a floating state in which the reference voltage Vref is no longer applied to the storage capacitor SC, and in this floating state, the first sampling 1^{st} sampling is performed.

Referring to (a) of FIG. 10 and FIG. 11, when the first gate voltage GATE1 is the gate high voltage, during the horizontal period, all of the switching transistors respectively connected to the plurality of second sub-pixels G arranged in the (6k-4)th column, the plurality of first sub-pixels R arranged in the (6k-2)th column, and the plurality of third sub-pixels B arranged in the 6k-th column in the odd-numbered row are turned on.

Referring to (b) in FIG. 10 and FIG. 11, when the second gate voltage GATE2 is the gate high voltage, during the horizontal period, all of the switching transistors respectively connected to the plurality of first sub-pixels R arranged in the (6k-5)th column, the plurality of third sub-pixels B arranged in the (6k-3)th column, and the plurality of second sub-pixels G arranged in the (6k-1)th column in the odd-numbered row are turned on.

Referring to FIG. 2, the voltage V2 of the second node N2 of the driving transistor DT can be initialized with the reference voltage Vref for sensing operation. The second node N2 of the driving transistor DT can be in a floating state in which the reference voltage Vref is no longer applied to the storage capacitor SC, and in this floating state, the second sampling 2^{nd} sampling is performed.

As described above, in the display panel according to the present disclosure, as the number of data lines and the multiple of the number of reference voltage lines are equal to each other, the sensing time taken for sensing each of the sub-pixels of R, G, and B of each of the four pixels PX arranged in the 2×2 matrix form can be reduced by 50%.

The display device 100 according to an embodiment of the present disclosure includes a display panel 110 including a plurality of pixels, a data driver 120 configured to supply a data voltage to the display panel 110 via a plurality of data lines, and a gate driver 130 configured to supply a gate signal to the display panel 110 via a plurality of gate lines, wherein the display panel 110 includes a first pixel including a plurality of sub-pixels, a second pixel disposed adjacent to the first pixel and including a plurality of sub-pixels, a first reference voltage line RVL1 configured to supply a reference voltage to at least one sub-pixel of the first pixel, a second reference voltage line RVL2 configured to supply a reference voltage to at least one sub-pixel of the second pixel, and a third reference voltage line RVL3 disposed between the first pixel and the second pixel.

According to an embodiment of the present disclosure, a driving circuit can be disposed on one or the other of both opposing sides in the column direction of the light-emission area of each of the plurality of sub-pixels of the first pixel and each of the plurality of sub-pixels of the second pixel, and the sub-pixels of the first pixel and the second pixel are alternately arranged with each other in the row direction in a manner flipped relative to each other in the column direction.

According to an embodiment of the present disclosure, the third reference voltage line RVL3 can supply the reference voltage to each of a sub-pixel to which the reference voltage is not supplied via the first reference voltage line RVL1 among the plurality of sub-pixels of the first pixel and a sub-pixel to which the reference voltage is not supplied via the second reference voltage line RVL2 among the plurality of sub-pixels of the second pixel.

As described above, in the display panel 110 according to the present disclosure, one reference voltage line is additionally disposed in addition to two existing reference voltage lines. Thus, the plurality of sub-pixels disposed in one row can be sensed twice, thereby reducing the sensing time by 50% compared to a conventional case of the four sensing times.

### B. Embodiment of Display Panel in Which Four Sub-Pixels are Disposed in One Pixel

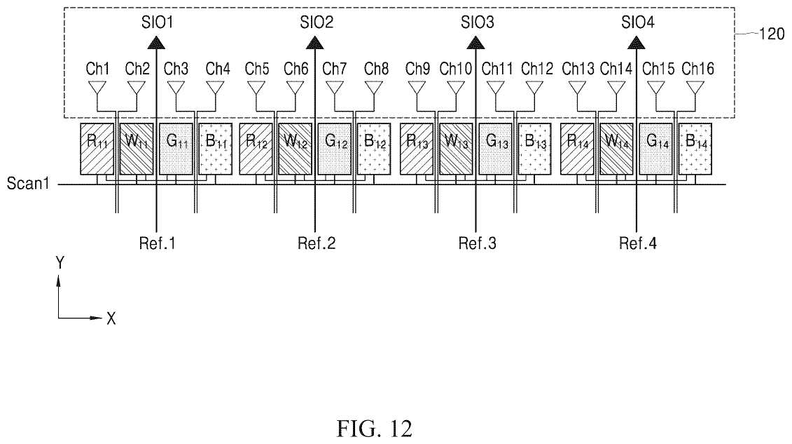

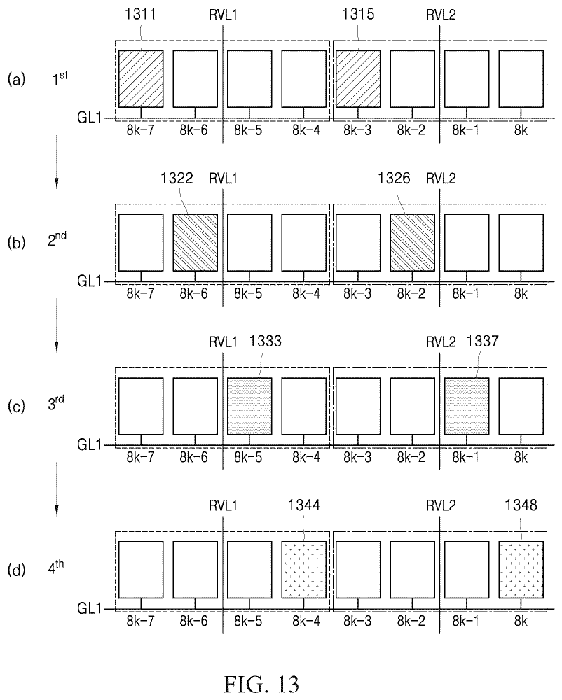

FIG. 12 is a first example diagram illustrating an arrangement relationship of sub-pixels when a pixel of a display panel according to embodiments of the present disclosure has four sub-pixels. FIG. 13 is an example diagram illustrating a sensing sequence of a plurality of sub-pixels in FIG. 12.

Referring to FIG. 12, the plurality of sub-pixels can include sub-pixels R₁₁, W₁₁, G₁₁, and B₁₁ of a first pixel sharing a first reference voltage line Ref.1 and sub-pixels R₁₂, W₁₂, G₁₂, and B₁₂ of a second pixel sharing a second reference voltage line Ref.2. Similarly, the plurality of sub-pixels can include sub-pixels R₁₃, W₁₃, G₁₃, and B₁₃ of a third pixel sharing the third reference voltage line Ref.3 and sub-pixels R₁₄, W₁₄, G₁₄, and B₁₄ of a fourth pixel sharing the fourth reference voltage line Ref.4.

The first reference voltage line Ref.1 is connected to the first sensing channel terminal SIO1, the second reference voltage line Ref.2 is connected to the second sensing channel terminal SIO2, the third reference voltage line Ref.3 is connected to the third sensing channel terminal SIO3, and the fourth reference voltage line Ref.4 is connected to the fourth sensing channel terminal SIO4. In addition, the data driver 120 can obtain a sensing voltage of each sub-pixel via a corresponding sensing channel thereto.

Although FIG. 12 illustrates an example in which the four pixels are disposed in one row, it is obvious that the display panel 110 according to the present disclosure can have a plurality of pixels arranged in each of a plurality of rows.

For example, the first pixel can include sub-pixels (e.g., a red sub-pixel R₁₁, a white sub-pixel W₁₁, a green sub-pixel G_{11,} and a blue sub-pixel B₁₁). According to an embodiment of the present disclosure, the second sub-pixel W of the first pixel can be disposed at a position adjacent to, in the first direction (e.g., the x-axis direction), the first sub-pixel R of the first pixel. In addition, the third sub-pixel G of the first pixel can be disposed at a position adjacent to, in the first direction (e.g., the x-axis direction), the second sub-pixel W of the first pixel. In addition, the fourth sub-pixel B of the first pixel can be disposed at a position adjacent to the third sub-pixel G of the first pixel in the first direction (e.g., the x-axis direction). The second pixel can include sub-pixels (e.g., a red sub-pixel R₁₂, a white sub-pixel W₁₂, a green sub-pixel _{G12}, and a blue sub-pixel B₁₂).

Similarly, the third pixel can include sub-pixels (e.g., a red sub-pixel R₁₃, a white sub-pixel W₁₃, a green sub-pixel G₁₃, and a blue sub-pixel B₁₃). The fourth pixel can include sub-pixels (e.g., a red sub-pixel R₁₄, a white sub-pixel W₁₄, a green sub-pixel G₁₄, and a blue sub-pixel B₁₄).

According to an embodiment of the present disclosure, an example has been described in which the sub-pixels R₁₁, W₁₁, G₁₁, and B₁₁ share the first reference voltage line Ref.1. However, according to the present disclosure, the sub-pixels R₁₂, W₁₂, G₁₂, and B₁₂ can share the second reference voltage line Ref.2, the sub-pixels R₁₃, W₁₃, G₁₃, and B₁₃ can share the third reference voltage line Ref.3, and the sub-pixels R₁₄, W₁₄, G₁₄, and B₁₄ can share the fourth reference voltage line Ref.4.

According to an embodiment of the present disclosure, each of the sub-pixels can be connected to each of the data lines. For example, 16 sub-pixels can receive data signals via 16 data lines, respectively. The display panel having such a structure can operate in a Single Rate Driving (SRD) manner.

According to an embodiment of the present disclosure, the data driver 120 can be connected to 16 data lines via 16 channel terminals, respectively. In addition, the data driver 120 can individually and independently drive each of the data lines. The 16 data channel terminals Ch1, Ch2, Ch3, Ch4, Ch5, Ch6, Ch7, Ch8, Ch9, Ch10, Ch11, Ch12, Ch13, Ch14, Ch15, and Ch16 can be connected to a data signal supply 300 of the data driver 120.

For example, the channels Ch1 and Ch2 are disposed between the adjacent sub-pixels R₁₁ and W₁₁ of the first pixel, and the channels Ch3 and Ch4 are disposed between the adjacent sub-pixels G₁₁ and B₁₁ of the first pixel.

In addition, the channels Ch5 and Ch6 are disposed between the adjacent sub-pixels R₁₂ and W₁₂ of the second pixel, and the channels Ch7 and Ch8 are disposed between the adjacent sub-pixels G₁₂ and B₁₂ of the second pixel.

In addition, the channels Ch9 and Ch10 are disposed between the adjacent sub-pixels R₁₃ and W₁₃ of the third pixel, and the channels Ch11 and Ch12 are disposed between the adjacent sub-pixels G₁₃ and B₁₃ of the third pixel.

In addition, the channels Ch13 and Ch14 are disposed between the adjacent sub-pixels R₁₄ and W₁₄ of the fourth pixel, and the channels Ch15 and Ch16 are disposed between the adjacent sub-pixels G₁₄ and B₁₄ of the fourth pixel.

According to an embodiment of the present disclosure, one scan signal line Scan1 can be disposed in one sub-pixel line. That is, the 16 sub-pixels can be commonly connected to one scan signal line Scan1. In addition, the 16 sub-pixels can commonly receive a scan signal via one scan signal line Scan 1.

According to an embodiment of the present disclosure, the display device 100 cannot simultaneously perform sensing operation on the red sub-pixel R₁₁, the white sub-pixel W₁₁, the green sub-pixel G₁₁ and the blue sub-pixel B₁₁ which are included in the sub-pixels R₁₁, W₁₁, G₁₁, and B₁₁ sharing the first reference voltage line Ref.1.

In addition, the display device 100 cannot simultaneously perform sensing operation on the red sub-pixel R₁₂, the white sub-pixel W₁₂, the green sub-pixel _{G12}, and the blue sub-pixel B₁₂ included in the sub-pixels R₁₂, W₁₂, G₁₂, and B₁₂ sharing the second reference voltage line Ref.2.

Likewise, the display device 100 cannot simultaneously perform sensing operation on the sub-pixels sharing the third reference voltage line Ref.3. The display device 100 cannot simultaneously perform sensing operation on the sub-pixels sharing the fourth reference voltage line Ref.4.

According to an embodiment of the present disclosure, the 16 sub-pixels SP can be connected to the 16 data lines, respectively. Accordingly, the 16 sub-pixels SP can receive data signals via corresponding data lines.

According to an embodiment of the present disclosure, the data driver 120 can individually and independently drive the 16 data lines.

The data driver 120 can supply different data signals to the 16 data lines. To this end, the data driver 120 can include 16 data channel terminals respectively connected to the 16 data lines. The 16 data channel terminals can be connected to the data signal supply 300.

Referring to FIGS. 12 and 13, two reference voltage lines RVL1 and RVL2 are used for compensation for the sub-pixels R, W, G, and B of two pixels PX.

As shown in (a) in FIG. 13, when the gate voltage GATE1 at the turn-on level is applied via the first gate line GL1 while the data voltage is being supplied, the gate signal is transmitted to the first sub-pixel R 1311 disposed in the (8k-7)th column and the first sub-pixel R 1315 disposed in the (8k-3)th column via the first gate line GL1, and the data voltage is charged into the first sub-pixel R 1311 disposed in the (8k-7)th column and the first sub-pixel R 1315 disposed in the (8k-3)th column, such that the first sub-pixel R 1311 disposed in the (8k-7)th column and the first sub-pixel R 1315 disposed in the (8k-3)th column emit light.

Thereafter, as shown in (b) in FIG. 13, the gate signal is transmitted to the second sub-pixel W 1322 disposed in the (8k-6)th column and the second sub-pixel W 1326 disposed in the (8k-2)th column via the first gate line GL1, and the data voltage is charged into the second sub-pixel W 1322 disposed in the (8k-6)th column and the second sub-pixel W 1326 disposed in the (8k-2)th column, such that the second sub-pixel W 1322 disposed in the (8k-6)th column and the second sub-pixel W 1326 disposed in the (8k-2)th column emit light.

Thereafter, as shown in (c) in FIG. 13, the gate signal is transmitted to the third sub-pixel G 1333 disposed in the (8k-5)th column and the third sub-pixel G 1337 disposed in the (8k-1)th column via the first gate line GL1, and the data voltage is charged into the third sub-pixel G 1333 disposed in the (8k-5)th column and the third sub-pixel G 1337 disposed in the (8k-1)th column, such that the third sub-pixel G 1333 disposed in the (8k-5)th column and the third sub-pixel G 1337 disposed in the (8k-1)th column emit light.

Thereafter, as shown in (d) in FIG. 13, the gate signal is transmitted to the fourth sub-pixel B 1344 disposed in the (8k-4)th column and the fourth sub-pixel B 1348 disposed in the 8k-th column via the first gate line GL1, and the data voltage is charged to the fourth sub-pixel B 1344 disposed in the (8k-4)th column and the fourth sub-pixel B 1348 disposed in the 8k-th column, such that the fourth sub-pixel B 1344 disposed in the (8k-4)th column and the fourth sub-pixel B 1348 disposed in the 8k-th column emit light.

As described above, the two reference voltage lines RVL1 and RVL2 can be used for compensation for the sub-pixels R, W, G, and B of the two pixels PX.

Referring to FIG. 13, the display panel 110 operates in a Single Rate Driving (SRD) manner. In this case, the driving and sensing ratio of each sub-pixel is 16:4 (i.e., 4:1), and a number of times of reference compensation is four times in total in one scan line.

However, as the number of the data lines DL and the number of the reference voltage lines RVL are not equal to each other, the sensing time taken for sensing the sub-pixels R, W, G, and B increases.

Accordingly, there is a need for a structure in which the number of data lines is equal to a multiple of the number of reference voltage lines, thereby reducing the sensing time taken for sensing the sub-pixels of R, W, G, and B.

According to an embodiment of the present disclosure, the display panel 110 in which four reference voltage lines are disposed for compensation for the sub-pixels R, W, G, and B of two pixels arranged in one row, and the display device 100 including the same are provided.

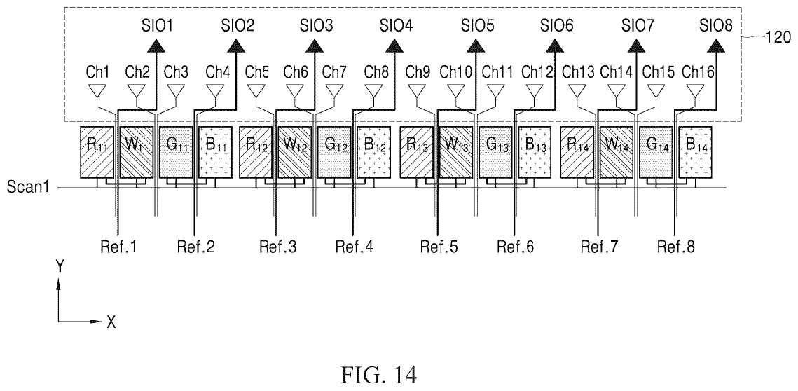

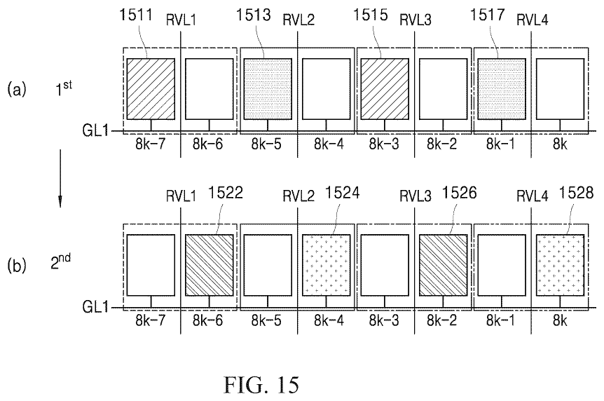

FIG. 14 is a second example diagram illustrating an arrangement relationship of sub-pixels when the pixel of the display panel according to embodiments of the present disclosure have four sub-pixels. FIG. 15 is an example diagram illustrating a sensing sequence of a plurality of sub-pixels in FIG. 14.

Referring to FIG. 14, the sub-pixels R₁₁ and W₁₁ of the first pixel share the first reference voltage line Ref.1, the sub-pixels G₁₁ and B₁₁ of the first pixel share the second reference voltage line Ref.2, the sub-pixels R₁₂ and W₁₂ of the second pixel share the third reference voltage line Ref.3, and the sub-pixels G₁₂ and B₁₂ of the second pixel share the fourth reference voltage line Ref.4.

Similarly, the sub-pixels R₁₃ and W₁₃ of the second pixel share the fifth reference voltage line Ref.5, the sub-pixels G13 and B₁₃ of the second pixel share the sixth reference voltage line Ref.6, the sub-pixels R₁₄ and W₁₄ of the second pixel share the seventh reference voltage line Ref.7, and the sub-pixels G₁₄ and B₁₄ of the second pixel share the eighth reference voltage line Ref.8.

The first reference voltage line Ref.1 is connected to the first sensing channel terminal SIO1, the second reference voltage line Ref.2 is connected to the second sensing channel terminal SIO2, the third reference voltage line Ref.3 is connected to the third sensing channel terminal SIO3, and the fourth reference voltage line Ref.4 is connected to the fourth sensing channel terminal SIO4.

Similarly, the fifth reference voltage line Ref.5 is connected to the fifth sensing channel terminal SIO5, the sixth reference voltage line Ref.6 is connected to the sixth sensing channel terminal SIO6, the seventh reference voltage line Ref.7 is connected to the seventh sensing channel terminal SIO7, and the eighth reference voltage line Ref.8 is connected to the eighth sensing channel terminal SIO8.

In addition, the data driver 120 can obtain a sensing voltage of each sub-pixel via a corresponding sensing channel thereto.

Although FIG. 14 illustrates an example in which four pixels are disposed in one row, it is obvious that the display panel 110 according to the present disclosure can have a plurality of pixels arranged in each of a plurality of rows.

For example, the first pixel can include sub-pixels (e.g., a red sub-pixel R₁₁, a white sub-pixel W₁₁, a green sub-pixel G_{11,} and a blue sub-pixel B₁₁). According to an embodiment of the present disclosure, the second sub-pixel W of the first pixel can be disposed at a position adjacent to, in the first direction (e.g., the x-axis direction), the first sub-pixel R of the first pixel. In addition, the third sub-pixel G of the first pixel can be disposed at a position adjacent to, in the first direction (e.g., the x-axis direction), the second sub-pixel W of the first pixel. In addition, the fourth sub-pixel B of the first pixel can be disposed at a position adjacent to the third sub-pixel G of the first pixel in the first direction (e.g., the x-axis direction). The second pixel can include sub-pixels (e.g., a red sub-pixel R₁₂, a white sub-pixel W₁₂, a green sub-pixel G₁₂, and a blue sub-pixel B₁₂).

Similarly, the third pixel can include sub-pixels (e.g., a red sub-pixel R₁₃, a white sub-pixel W₁₃, a green sub-pixel G₁₃, and a blue sub-pixel B₁₃). The fourth pixel can include sub-pixels (e.g., a red sub-pixel R₁₄, a white sub-pixel W₁₄, a green sub-pixel G₁₄, and a blue sub-pixel B₁₄).

According to an embodiment of the present disclosure, each of the sub-pixels can be connected to each of the data lines DL. For example, 16 sub-pixels can receive data signals via 16 data lines DL, respectively.

According to an embodiment of the present disclosure, the data driver 120 can be connected to 16 data lines via 16 channel terminals, respectively. In addition, the data driver 120 can individually and independently drive each of the data lines DL. The 16 data channel terminals Ch1, Ch2, Ch3, Ch4, Ch5, Ch6, Ch7, Ch8, Ch9, Ch10, Ch11, Ch12, Ch13, Ch14, Ch15, and Ch16 can be connected to the data signal supply 300 of the data driver 120.

For example, the channel Ch1 is disposed between the adjacent sub-pixels R₁₁ and W₁₁ of the first pixel, the channels Ch2 and Ch3 are disposed between the adjacent sub-pixels W₁₁ and G₁₁ of the first pixel, and the channel Ch4 is disposed between the adjacent sub-pixels G₁₁ and B₁₁ of the first pixel.

In addition, the channel Ch5 is disposed between the adjacent sub-pixels R₁₂ and W₁₂ of the second pixel, the channels Ch6 and Ch7 are disposed between the adjacent sub-pixels W₁₂ and G₁₂ of the second pixel, and the channel Ch8 is disposed between the adjacent sub-pixels G₁₂ and B₁₂ of the second pixel.

In addition, the channel Ch9 is disposed between the adjacent sub-pixels R₁₃ and W₁₃ of the third pixel, the channels Ch10 and Ch11 are disposed between the adjacent sub-pixels W₁₃ and G₁₃ of the third pixel, and the channel Ch12 is disposed between the adjacent sub-pixels G₁₃ and B₁₃ of the third pixel.

In addition, the channel Ch13 is disposed between the adjacent sub-pixels R₁₄ and W₁₄ of the fourth pixel, the channels Ch14 and Ch15 are disposed between the adjacent sub-pixels W₁₄ and G₁₄ of the fourth pixel, and the channel Ch16 is disposed between the adjacent sub-pixels G₁₄ and B₁₄ of the fourth pixel.

According to an embodiment of the present disclosure, one scan signal line Scan1 can be disposed in one sub-pixel line. That is, the 16 sub-pixels can be commonly connected to one scan signal line Scan1. In addition, the 16 sub-pixels SP can commonly receive a scan signal via one scan signal line Scan 1.

For example, the display device 100 cannot simultaneously perform sensing operation on the red sub-pixel R₁₁ and the white sub-pixel W₁₁ included in the sub-pixels R₁₁ and W₁₁ sharing the first reference voltage line Ref.1. Similarly, the display device 100 cannot simultaneously perform the sensing operation on the green sub-pixel G₁₁ and the blue sub-pixel B₁₁ included in the sub₋ₚᵢₓₑₗₛ G₁₁ and B₁₁ sharing the second reference voltage line Ref.2

In addition, the display device 100 cannot simultaneously perform sensing operation on the red sub-pixel R₁₂ and the white sub-pixel W₁₂ included in the sub-pixels R₁₂, and W₁₂ sharing the third reference voltage line Ref.3. Similarly, the display device 100 cannot simultaneously perform sensing operation on the green sub-pixel G₁₂ and the blue sub-pixel B₁₂ included in the sub-pixels G₁₂ and B₁₂ sharing the fourth reference voltage line Ref.4

According to an embodiment of the present disclosure, the 16 sub-pixels SP can be connected to the 16 data lines DL, respectively. Accordingly, the 16 sub-pixels SP can receive data signals via corresponding data lines.

According to an embodiment of the present disclosure, the data driver 120 can individually and independently drive the 16 data lines.

The data driver 120 can supply different data signals to 16 data lines. To this end, the data driver 120 can include 16 data channel terminals respectively connected to the 16 data lines. The 16 data channel terminals can be connected to the data signal supply 300.

Referring to FIG. 14, the display panel 110 operates in a Single Rate Driving (SRD) manner to which a source drive IC of a double rate driving (DRD) is applied. In this case, a driving and sensing ratio of each sub-pixel is 16:8 (that is, 2:1), and the number of times of reference compensation in one scan line is four in total.

Referring to FIGS. 14 and 15, the four reference voltage lines RVL1, RVL2, RVL3, and RVL4 are used for compensation for the sub-pixels R, W, G, and B of the two pixels PX.

As shown in (a) in FIG. 15, when the gate voltage GATE1 at the turn-on level is applied via the first gate line GL1 while the data voltage is being supplied, the gate signal is transmitted to the first sub-pixel R 1511 disposed in the (8k-7)th column, the third sub-pixel G 1513 disposed in the (8k-5)th column, the first sub-pixel R 1515 disposed in the (8k-3)th column, and the third sub-pixel G 1517 disposed in the (8k-1)th column via the first gate line GL1.

In addition, the first sub-pixel R 1511 disposed in the (8k-7)th column, the third sub-pixel G 1513 disposed in the (8k-5)th column, the first sub-pixel R 1515 disposed in the (8k-3)th column, and the third sub-pixel G 1517 disposed in the (8k-1)th column are charged with a data voltage, and thus the first sub-pixel R 1511 disposed in the (8k-7)th column, the third sub-pixel G 1513 disposed in the (8k-5)th column, the first sub-pixel R 1515 disposed in the (8k-3)th column, and the third sub-pixel G 1517 disposed in the (8k-1)th column emit light.

Thereafter, as shown in (b) in FIG. 15, the gate signal is transmitted to the second sub-pixel W 1522 disposed in the (8k-6)th column, the fourth sub-pixel B 1524 disposed in the (8k-4)th column, the second sub-pixel W 1526 disposed in the (8k-2)th column, and the fourth sub-pixel B 1528 disposed in the 8k-th column via the first gate line GL1.

In addition, the second sub-pixel W 1522 disposed in the (8k-6)th column, the fourth sub-pixel B 1524 disposed in the (8k-4)th column, the second sub-pixel W 1526 disposed in the (8k-2)th column, and the fourth sub-pixel B 1528 disposed in the 8k-th column are charged with the data voltage, and thus the second sub-pixel W 1522 disposed in the (8k-6)th column, the fourth sub-pixel B 1524 disposed in the (8k-4)th column, the second sub-pixel W 1526 disposed in the (8k-2)th column, and the fourth sub-pixel B 1528 disposed in the 8k-th column emit light.

As described above, the four reference voltage lines RVL1, RVL2, RVL3, and RVL4 can be used to compensate for the sub-pixels R, W, G, and B of the two pixels PX.

Referring to FIG. 15, the driving and sensing ratio of each sub-pixel of the display panel 110 is 16:8 (i.e., 2:1), and the number of times of reference compensation in one scan line is four in total.

As illustrated in FIGS. 14 and 15, the plurality of reference voltage lines RVL are added to the display panel 110 operating in the SRD driving manner, such that the driving ratio relative to the sensing ratio of the sub-pixel can be lowered, and accordingly, the sensing time taken for sensing the sub-pixel can be reduced.

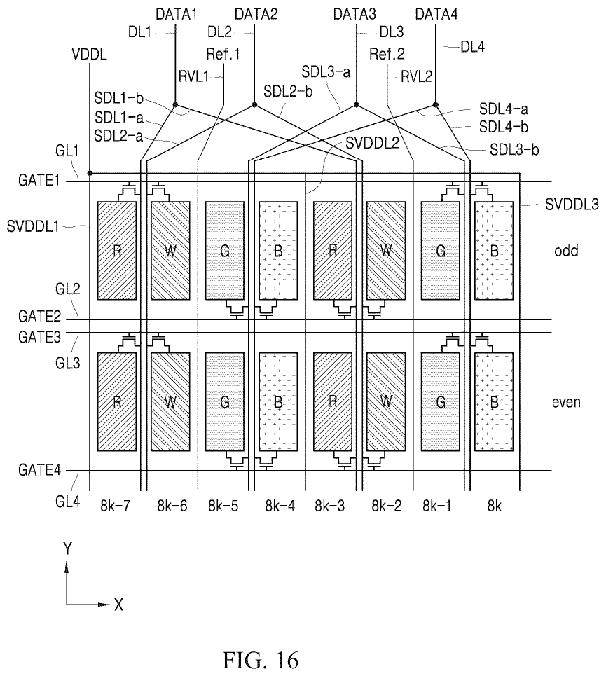

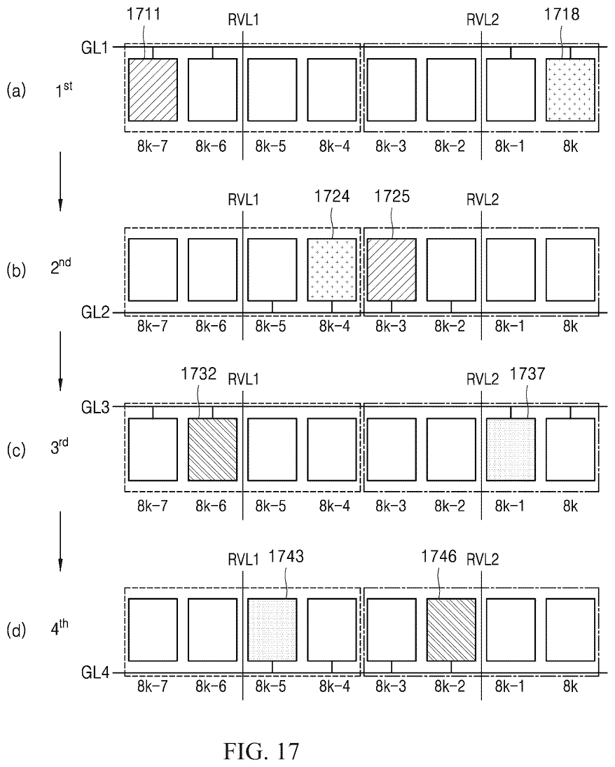

FIG. 16 is a third example diagram illustrating an arrangement relationship of sub-pixels when the pixel of the display panel according to embodiments of the present disclosure have four sub-pixels. FIG. 17 is an example diagram illustrating a sensing sequence of a plurality of sub-pixels in FIG. 16.

In FIG. 16, for convenience of illustration, four pixels PX arranged in a 2×2 matrix form are illustrated. An arrangement relationship of four pixels PX arranged in a 2×2 matrix form can be repeated in the display area DA. In addition, a transistor disposed between the sub-pixels R, W, B, and G and the data line means the switching transistor SWT described in FIG. 2.

According to an embodiment of the present disclosure, each of the plurality of data lines DL1, DL2, DL3, and DL4 can divide into a plurality of sub-data lines SDL1-a, SDL1-b, SDL2-a, SDL2-b, SDL3-a, SDL3-b, SDL4-a, and SDL4-b.

Specifically, the first data line DL1 can divide into a plurality of first sub-data lines SDL1-a and SDL1-b, and the second data line DL2 can divide into a plurality of second sub-data lines SDL2-a and SDL2-b.

The third data line DL3 can divide into the plurality of third sub-data lines SDL3-a and SDL3-b, and the fourth data line DL4 can divide into the plurality of fourth sub-data lines SDL4-a and SDL4-b.

According to an embodiment of the present disclosure, the first sub-data lines SDL1-a and SDL1-b can include a (1-a)th sub-data line SDL1-a and a (1-b)th sub-data line SDL1-b, and the second sub-data lines SDL2-a and SDL2-b can include a (2-a)th sub-data line SDL2-a and a (2-b)th sub-data line SDL2-b.

The third sub-data lines SDL3-a and SDL3-b can include a (3-a)th sub-data line SDL3-a and a (3-b)th sub-data line SDL3-b, and the fourth sub-data lines SDL4-a and SDL4-b can include a (4-a)th sub-data line SDL4-a and a (4-b)th sub-data line SDL4-b.

The high potential voltage line VDDL can divide into a plurality of sub-high potential voltage lines SVDDL1, SVDDL2, and SVDDL3. Each of the sub-high potential voltage lines can be disposed between adjacent ones of the plurality of pixels.

According to an embodiment of the present disclosure, the first sub-high potential voltage line SVDDL1 can be disposed on one side (e.g., left side) of the sub-pixel in the (8k-7)th column, the second sub-high potential voltage line SVDDL2 can be disposed between the sub-pixel B in the (8k-4)th column and the sub-pixel R in the (8k-3)th column, and the third sub-high potential voltage line SVDDL3 can be disposed on the other side (e.g., right side) of the sub-pixel in the 8k-th column.

According to an embodiment of the present disclosure, the first reference voltage line RVL1 can be disposed between the sub-pixel W in the (8k-6)th column and the sub-pixel G in the (8k-5)th column, and the second reference voltage line RVL2 can be disposed between the sub-pixel W in the (8k-2)th column and the sub-pixel G in the (8k-1)th column.

According to an embodiment of the present disclosure, one pixel PX can include four sub-pixels R, W, G, and B. For example, as shown in FIG. 16, the pixel PX can include a first sub-pixel R, a second sub-pixel W, a third sub-pixel G, and a fourth sub-pixel B. For example, the first sub-pixel R can be a red sub-pixel, the second sub-pixel W can be a white sub-pixel, the third sub-pixel G can be a green sub-pixel, and the fourth sub-pixel B can be a blue sub-pixel. However, the present disclosure is not limited thereto, and the plurality of sub-pixels can include sub-pixels emitting light of various colors such as magenta, yellow, and cyan.

According to an embodiment of the present disclosure, the second sub-pixel W of the first pixel can be disposed at a position adjacent to, in the first direction (e.g., the x-axis direction), the first sub-pixel R of the first pixel. In addition, the third sub-pixel G of the first pixel can be disposed at a position adjacent to, in the first direction (e.g., the x-axis direction), the second sub-pixel W of the first pixel. In addition, the fourth sub-pixel B of the first pixel can be disposed at a position adjacent to the third sub-pixel G of the first pixel in the first direction (e.g., the x-axis direction). Here, the second sub-pixel W may be referred to as “a first line-sub-pixel”, and the third sub-pixel G may be referred to as “a second line-sub-pixel”.

In addition, the plurality of sub-pixels of the same color can be disposed in the same column. That is, the plurality of first sub-pixels R can be disposed in the same column, the plurality of second sub-pixels W can be disposed in the same column, the plurality of third sub-pixels G can be disposed in the same column, and the plurality of fourth sub-pixels B can be disposed in the same column.

More specifically, as illustrated in FIG. 16, the plurality of first sub-pixels R can be arranged in a (8k-7)th column and a (8k-3)th column, and the plurality of second sub-pixels W can be arranged in a (8k-6)th column and a (8k-2)th column. In addition, the plurality of third sub-pixels G can be arranged in a (8k-5)th column and a (8k-1)th column, and the plurality of fourth sub-pixels B can be arranged in a (8k-4)th column and a 8k-th column. Here, k means a natural number greater than or equal to 1.

That is, the first sub-pixel R, the second sub-pixel W, the third sub-pixel G, and the fourth sub-pixel B can be sequentially and repeatedly arranged along one odd-numbered row or one even-numbered row.

According to an embodiment of the present disclosure, the sub-pixels of the first pixel and the second pixel disposed adjacent to each other in the first direction (e.g., the x-axis direction) can be alternately arranged with each other in the row direction in a manner flipped relative to each other in a column direction.

In addition, each of the first sub-pixel R and the second sub-pixel W of the first pixel and each of the third sub-pixel G and the fourth sub-pixel B of the first pixel can have structures flipped in a column direction relative to each other.

According to an embodiment of the present disclosure, each of the plurality of first sub-data lines SDL1-a and SDL1-b can be disposed adjacent to the plurality of first sub-pixels R and be respectively connected to the plurality of first sub-pixels R.

Specifically, the (1-a)th sub-data line SDL1-a can be disposed between the plurality of first sub-pixels R arranged in a (8k-7)th column and the plurality of second sub-pixels W arranged in a (8k-6)th column, and can be electrically connected to the plurality of first sub-pixels R arranged in the (8k-7)th column. In addition, the (1-b)th sub-data line SDL1-b can be disposed between the plurality of first sub-pixels R arranged in a (8k-3)th column and the plurality of second sub-pixels W arranged in a (8k-2)th column, and can be electrically connected to the plurality of first sub-pixels R arranged in the (8k-3)th column.

According to an embodiment of the present disclosure, each of the plurality of second sub-data lines SDL2-a and SDL2-b can be disposed adjacent to the plurality of second sub-pixels W and can be connected to the plurality of second sub-pixels W.

Specifically, the (2-a)th sub-data line SDL2-a can be disposed between the plurality of first sub-pixels R arranged in a (8k-7)th column and the plurality of second sub-pixels W arranged in a (8k-6)th column, and can be electrically connected to the plurality of second sub-pixels W arranged in the (8k-6)th column. In addition, the (2-b)th sub-data line SDL2-b can be disposed between the plurality of first sub-pixels R arranged in a (8k-3)th column and the plurality of second sub-pixels W arranged in a (8k-2)th column and be electrically connected to the plurality of second sub-pixels W arranged in the (8k-2)th column.

According to an embodiment of the present disclosure, each of the plurality of third sub-data lines SDL3-a and SDL3-b can be disposed adjacent to the plurality of third sub-pixels G and can be connected to the plurality of third sub-pixels G.

Specifically, the (3-a)th sub-data line SDL3-a can be disposed between the plurality of third sub-pixels G arranged in a (8k-5)th column and the plurality of fourth sub-pixels B arranged in a (8k-4)th column, and can be electrically connected to the plurality of third sub-pixels G arranged in the (8k-5)th column. In addition, the (3-b)th sub-data line SDL3-b can be disposed between the plurality of third sub-pixels G arranged in a (8k-1)th column and the plurality of fourth sub-pixels B arranged in a 8k-th column, and can be electrically connected to the plurality of third sub-pixels G arranged in the (8k-1)th column.

According to an embodiment of the present disclosure, each of the plurality of fourth sub-data lines SDL4-a and SDL4-b can be disposed adjacent to the plurality of fourth sub-pixels B and can be connected to the plurality of fourth sub-pixels B.

Specifically, the (4-a)th sub-data line SDL4-a can be disposed between the plurality of third sub-pixels G arranged in a (8k-5)th column and the plurality of fourth sub-pixels B arranged in a (8k-4)th column, and can be electrically connected to the plurality of fourth sub-pixels B arranged in the (8k-4)th column. The (4-b)th sub-data lines SDL4-b can be disposed between the plurality of third sub-pixels G arranged in a (8k-1)th column and the plurality of fourth sub-pixels B arranged in a 8k-th column, and can be electrically connected to the plurality of fourth sub-pixels B arranged in the 8k-th column.

According to an embodiment of the present disclosure, a first data voltage DATA1 as a red data voltage can be applied to the first data line DL1, and a second data voltage DATA2 as a white data voltage can be applied to the second data line DL2. In addition, a third data voltage DATA3 as a green data voltage can be applied to the third data line DL3, and a fourth data voltage DATA4 as a blue data voltage can be applied to the fourth data line DL4.

Accordingly, the first data voltage DATA1 as a red data voltage can also be applied to the plurality of first sub-data lines SDL1-a and SDL1-b, and the second data voltage DATA2 as a white data voltage can also be applied to the plurality of second sub-data lines SDL2-a and SDL2-b. In addition, the third data voltage DATA3 as a green data voltage can also be applied to the plurality of third sub-data lines SDL3-a and SDL3-b, and the fourth data voltage DATA4 as a blue data voltage can also be applied to the plurality of fourth sub-data lines SDL4-a and SDL4-b.

According to an embodiment of the present disclosure, each of the plurality of gate lines GL1 to GL4 can be disposed on each of both opposing sides in the column direction of a row of the plurality of sub-pixels R, W, G and B. Two gate lines GL2 and GL3 can be disposed between adjacent rows of the plurality of sub-pixels R, W, G and B.

Specifically, referring to FIG. 16, the first gate line GL1 and the second gate line GL2 can be respectively disposed on both opposing sides in the column direction of the plurality of sub-pixels R, W, G and B of the odd-numbered row, while the third gate line GL3 and the fourth gate line GL4 can be respectively disposed on both opposing sides in the column direction of the plurality of sub-pixels R, W, G and B of the even-numbered row. Accordingly, the second gate line GL2 and the third gate line GL3 can be disposed between the plurality of sub-pixels R, W, G and B arranged in the odd-numbered row and the plurality of sub-pixels R, W, G and B arranged in the even-numbered row.

Each of the plurality of pixels PX can be connected to the same gate line GL1 to GL4, and adjacent pixels PX among the plurality of pixels PX can be connected to different gate lines GL1 to GL4.

Specifically, referring to FIG. 16, the sub-pixels R and W respectively disposed in the (8k-7)th column and the (8k-6)th column of the odd-numbered row odd and the sub-pixels G and B respectively disposed in the (8k-1)th column and the 8k-th column of the odd-numbered row odd are connected to the first gate line GL1. The sub-pixels G and B respectively disposed in the (8k-5)th column and the (8k-4)th column of the odd-numbered row odd and the sub-pixels R and W respectively disposed in the (8k-3)th column and the (8k-2)th column of the odd-numbered row odd can be connected to the second gate line GL2.

In addition, the sub-pixels R and W respectively disposed in the (8k-7)th column and the (8k-6)th column of the even-numbered row even and the sub-pixels G and B respectively disposed in the (8k-1)th column and the 8k-th column of the even-numbered row even are connected to the third gate line GL3. The sub-pixels G and B respectively disposed in the (8k-5)th column and the (8k-4)th column of the even-numbered row even and the sub-pixels R and W respectively disposed in the (8k-3)th column and the (8k-2)th column of the even-numbered row even can be connected to the fourth gate line GL4.

Each of the sub-high potential voltage lines SVDDL1, SVDDL2, and SVDDL3 can be disposed between adjacent ones of the plurality of pixels PX.

Referring to FIG. 16, the display panel 110 operates in a Double Rate Driving (DRD) manner. In this case, the driving and sensing ratio of each sub-pixel SP is 4:2 (that is, 2:1), and the number of times of reference compensation in one scan line SL is a total of four times.

Hereinafter, a sensing sequence of sub-pixels when a pixel of a display panel according to an embodiment of the present disclosure has four sub-pixels will be described with reference to FIGS. 16 and 17

As shown in (a) in FIG. 17, when the gate voltage GATE1 at the turn-on level is applied via the first gate line GL1 while the data voltage is being supplied, the gate signal is transmitted to the first sub-pixel R 1711 disposed in the (8k-7)th column and the fourth sub-pixel B 1718 disposed in the 8k-th column via the first gate line GL1, and the data voltage is charged to the first sub-pixel R 1711 disposed in the (8k-7)th column and the fourth sub-pixel B 1718 disposed in the 8k-th column. Thus, the first sub-pixel R 1711 disposed in the (8k-7)th column and the fourth sub-pixel B 1718 disposed in the 8k-th column emit light.

Thereafter, as shown in (b) of FIG. 17, the gate signal is transmitted to the fourth sub-pixel B 1724 disposed in the (8k-4)th column and the first sub-pixel R 1725 disposed in the (8k-3)th column via the second gate line GL2, and the fourth sub-pixel B 1724 disposed in the (8k-4)th column and the first sub-pixel R 1725 disposed in the (8k-3)th column are charged with the data voltage, such that the fourth sub-pixel B 1724 disposed in the (8k-4)th column and the first sub-pixel R 1725 disposed in the (8k-3)th column emit light.

Thereafter, as shown in (c) in FIG. 17, the gate signal is transmitted to the second sub-pixel W 1732 disposed in the (8k-6)th column and the third sub-pixel G 1737 disposed in the (8k-1)th column via the third gate line GL3, and the data voltage is charged into the second sub-pixel W 1732 disposed in the (8k-6)th column and the third sub-pixel G 1737 disposed in the (8k-1)th column, such that the second sub-pixel W 1732 disposed in the (8k-6)th column and the third sub-pixel G 1737 disposed in the (8k-1)th column emit light.

Thereafter, as shown in (d) in FIG. 17, the gate signal is transmitted to the third sub-pixel G 1743 disposed in the (8k-5)th column and the second sub-pixel W 1746 disposed in the (8k-2)th column via the fourth gate line GL4, and the data voltage is charged to the third sub-pixel G 1743 disposed in the (8k-5)th column and the second sub-pixel W 1746 disposed in the (8k-2)th column, such that the third sub-pixel G 1743 disposed in the (8k-5)th column and the second sub-pixel W 1746 disposed in the (8k-2)th column emit light.

As described above, two reference voltage lines RVL1 and RVL2 can be used for compensation for the sub-pixels R, W, G, and B of the two pixels PX.

Referring to FIG. 17, the driving and sensing ratio of each sub-pixel of the display panel 110 is 4:2 (i.e., 2:1), and the number of times of reference compensation in one scan line is four in total.

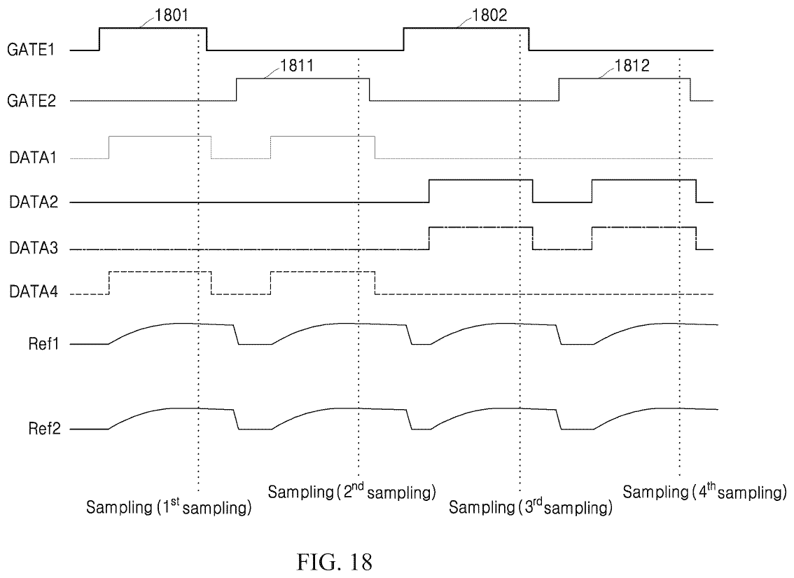

FIG. 18 is a timing diagram of a gate voltage, a data voltage, and a voltage charged into a storage capacitor according to an embodiment of the present disclosure according to FIG. 17.

Referring to FIG. 16 and (a) in FIG. 17, when the first gate voltage GATE1 is the gate high voltage 1801, during the horizontal period, all of the switching transistors connected to the plurality of first sub-pixels R disposed in the (8k-7)th column and the plurality of fourth sub-pixels B disposed in the 8k-th column in the odd-numbered row are turned on. In this case, the voltage V2 of the second node N2 of the driving transistor DT can be initialized with the reference voltage Vref for sensing operation. The second node N2 of the driving transistor DT can be in a floating state in which the reference voltage Vref is no longer applied to the storage capacitor SC, and in this floating state, the first sampling 1^{st} sampling is performed.

Referring to FIG. 16 and (b) in FIG. 17, when the second gate voltage GATE2 is the gate high voltage 1811, during the horizontal period, all of the switching transistors connected to the plurality of fourth sub-pixels B disposed in the (8k-4)th column and the plurality of first sub-pixels R disposed in the (8k-3)th column in the odd-numbered row are turned on. In this case, the voltage V2 of the second node N2 of the driving transistor DT can be initialized with the reference voltage Vref for sensing operation. The second node N2 of the driving transistor DT can be in a floating state in which the reference voltage Vref is no longer applied to the storage capacitor SC, and in this floating state, the second sampling 2^{nd} sampling is performed.

Referring to FIG. 16 and (c) in FIG. 17, when the first gate voltage GATE1 is the gate high voltage 1802, during the horizontal period, all of the switching transistors respectively connected to the plurality of second sub-pixels W disposed in the (8k-6)th column and the plurality of third sub-pixels G disposed in the (8k-1)th column in the odd-numbered row are turned on. In this case, the voltage V2 of the second node N2 of the driving transistor DT can be initialized with the reference voltage Vref for sensing operation. The second node N2 of the driving transistor DT can be in a floating state in which the reference voltage Vref is no longer applied to the storage capacitor SC, and in this floating state, the third sampling 3^{rd} sampling is performed.

Referring to FIG. 16 and (d) in FIG. 17, when the second gate voltage GATE2 is the gate high voltage 1812, during the horizontal period, all of the switching transistors connected to the plurality of third sub-pixels G disposed in the (8k-5)th column and the plurality of second sub-pixels W disposed in the (8k-2)th column in the odd-numbered row are turned on. In this case, the voltage V2 of the second node N2 of the driving transistor DT can be initialized with the reference voltage Vref for sensing operation. The second node N2 of the driving transistor DT can be in a floating state in which the reference voltage Vref is no longer applied to the storage capacitor SC, and in this floating state, the fourth sampling 4^{th} sampling is performed.

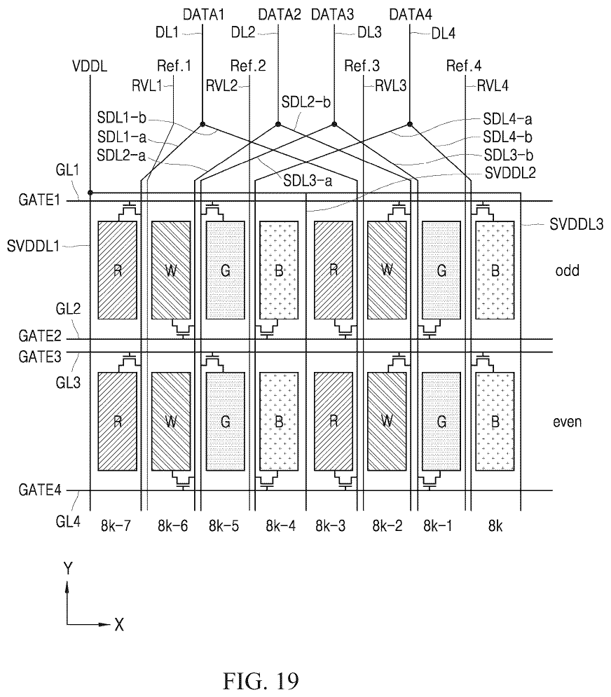

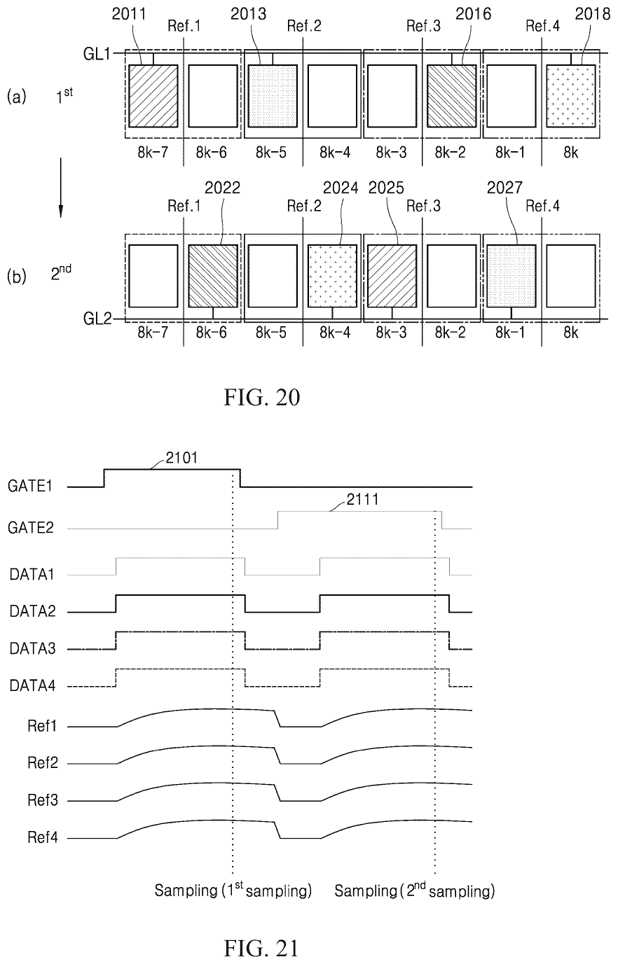

FIG. 19 is a fourth example diagram illustrating an arrangement relationship of sub-pixels when each of the pixels of the display panel according to embodiments of the present disclosure has four sub-pixels. FIG. 20 is an example diagram illustrating a sensing sequence of a plurality of sub-pixels in FIG. 19.

In FIG. 19, for convenience of description, four pixels PX arranged in a 2×2 matrix form are illustrated, and an arrangement relationship of four pixels PX arranged in a 2×2 matrix form can be repeated in the display area DA. In addition, a transistor disposed between the adjacent sub-pixels R, W, G, and B and the data line means the switching transistor SWT described in FIG. 2.

According to an embodiment of the present disclosure, each of the plurality of data lines DL1, DL2, DL3, and DL4 can divide into a plurality of sub-data lines SDL1-a, SDL1-b, SDL2-a, SDL2-b, SDL3-a, SDL3-b, SDL4-a, and SDL4-b.

Specifically, the first data line DL1 can divide into a plurality of first sub-data lines SDL1-a and SDL1-b, and the second data line DL2 can divide into a plurality of second sub-data lines SDL2-a and SDL2-b.

The third data line DL3 can divide into the plurality of third sub-data lines SDL3-a and SDL3-b, and the fourth data line DL4 can divide into the plurality of fourth sub-data lines SDL4-a and SDL4-b.

According to an embodiment of the present disclosure, the first sub-data lines SDL1-a and SDL1-b can include a (1-a)th sub-data line SDL1-a and a (1-b)th sub-data line SDL1-b, and the second sub-data lines SDL2-a and SDL2-b can include a (2-a)th sub-data line SDL2-a and a (2-b)th sub-data line SDL2-b.

The third sub-data lines SDL3-a and SDL3-b can include a (3-a)th sub-data line SDL3-a and a (3-b)th sub-data line SDL3-b, and the fourth sub-data lines SDL4-a and SDL4-b can include a (4-a)th sub-data line SDL4-a and a (4-b)th sub-data line SDL4-b.

According to an embodiment of the present disclosure, the high potential voltage line VDDL can divide into a plurality of sub-high potential voltage lines SVDDL1, SVDDL2, and SVDDL3. Each of the sub-high potential voltage lines can be disposed between adjacent ones of the plurality of pixels PX.

According to an embodiment of the present disclosure, the first sub-high potential voltage line SVDDL1 can be disposed on one side (e.g., left side) of the sub-pixel in the (8k-7)th column, the second sub-high potential voltage line SVDDL2 can be disposed between the sub-pixel B in the (8k-4)th column and the sub-pixel R in the (8k-3)th column, and the third sub-high potential voltage line SVDDL3 can be disposed on the other side (e.g., right side) of the sub-pixel in the 8k-th column.

According to an embodiment of the present disclosure, the first reference voltage line RVL1 can be disposed between the sub-pixel R of the (8k-7)th column and the sub-pixel W of the (8k-6)th column, and the second reference voltage line RVL2 can be disposed between the sub-pixel G of the (8k-5)th column and the sub-pixel B of the (8k-4)th column. In addition, the third reference voltage line RVL3 can be disposed between the sub-pixel R of the (8k-3)th column and the sub-pixel W of the (8k-2)th column, and the fourth reference voltage line RVL 4 can be disposed between the sub-pixel G of the (8k-1)th column and the sub-pixel B of the 8k-th column.

According to an embodiment of the present disclosure, one pixel PX can include four sub-pixels R, W, G, and B. For example, as shown in FIG. 19, the pixel PX can include a first sub-pixel R, a second sub-pixel W, a third sub-pixel G, and a fourth sub-pixel B. For example, the first sub-pixel R can be a red sub-pixel, the second sub-pixel W can be a white sub-pixel, the third sub-pixel G can be a green sub-pixel, and the fourth sub-pixel B can be a blue sub-pixel. However, the present disclosure is not limited thereto, and the plurality of sub-pixels can include sub-pixels emitting light of various colors such as magenta, yellow, and cyan.

According to an embodiment of the present disclosure, the second sub-pixel W of the first pixel can be disposed at a position adjacent to, in the first direction (e.g., the x-axis direction), the first sub-pixel R of the first pixel. In addition, the third sub-pixel B of the first pixel can be disposed at a position adjacent to, in the first direction (e.g., the x-axis direction), the second sub-pixel W of the first pixel. In addition, the fourth sub-pixel B of the first pixel can be disposed at a position adjacent to the third sub-pixel G of the first pixel in the first direction (e.g., the x-axis direction). Here, the first sub-pixel R may be referred to as “a first line-sub-pixel”, and the second sub-pixel W may be referred to as “a second line-sub-pixel”. Alternatively, the second sub-pixel W may be referred to as “a first line-sub-pixel”, and the third sub-pixel G may be referred to as “a second line-sub-pixel”. Alternatively, the third sub-pixel G may be referred to as “a first line-sub-pixel”, and the fourth sub-pixel B may be referred to as “a second line-sub-pixel”.

In addition, the plurality of sub-pixels of the same color can be disposed in the same column. That is, the plurality of first sub-pixels R can be disposed in the same column, the plurality of second sub-pixels W can be disposed in the same column, the plurality of third sub-pixels G can be disposed in the same column, and the plurality of fourth sub-pixels B can be disposed in the same column.

More specifically, as illustrated in FIG. 19, the plurality of first sub-pixels R can be disposed in each of the (8k-7)th column and the (8k-3)th column, and the plurality of second sub-pixels W can be disposed in each of the (8k-6)th column and the (8k-2)th column. In addition, the plurality of third sub-pixels G can be disposed in each of the (8k-5)th column and the (8k-1)th column, and the plurality of fourth sub-pixels B can be disposed in each of the (8k-4)th column and the 8k-th column. In this regard, k means a natural number greater than or equal to 1.

That is, the first sub-pixel R, the second sub-pixel W, the third sub-pixel G, and the fourth sub-pixel B can be sequentially and repeatedly arranged along odd-numbered row or one even-numbered row.

According to an embodiment of the present disclosure, the sub-pixels of the first pixel and the second pixel disposed adjacent to each other in the first direction (e.g., the x-axis direction) can be alternately arranged with each other in the row direction in a manner flipped relative to each other in a column direction.

In addition, each of the first sub-pixel R and the third sub-pixel G of the first pixel and each of the second sub-pixel W and the fourth sub-pixel B of the first pixel can have structures flipped in a column direction relative to each other. That is, the first sub-pixel R of the first pixel and the second sub-pixel W of the first pixel can have structures flipped in a column direction relative to each other. That is, the third sub-pixel G of the first pixel and fourth sub-pixel B of the first pixel can have structures flipped in a column direction relative to each other. That is, the driving circuits of the sub-pixels can be arranged in the staggered manner in the row direction.

In addition, each of the first sub-pixel R and the third sub-pixel G of the second pixel and each of the second sub-pixel W and the fourth sub-pixel B of the second pixel can have structures flipped in a column direction relative to each other. That is, the first sub-pixel R of the second pixel and the second sub-pixel W of the second pixel can have structures flipped in a column direction relative to each other. That is, the third sub-pixel G of the second pixel and fourth sub-pixel B of the second pixel can have structures flipped in a column direction relative to each other. That is, the driving circuits of the sub-pixels can be arranged in the staggered manner in the row direction.

According to an embodiment of the present disclosure, the plurality of first sub-data lines SDL1-a and SDL1-b can be disposed adjacent to the plurality of first sub-pixels R so as to be connected to the plurality of first sub-pixels R.

Specifically, the (1-a)th sub-data line SDL1-a can be disposed between the plurality of first sub-pixels R disposed in the (8k-7)th column and the plurality of second sub-pixels W disposed in the (8k-6)th column, and can be electrically connected to the plurality of first sub-pixels R disposed in the (8k-7)th column. The (1-b)th sub-data lines SDL1-b can be disposed between the plurality of first sub-pixels R disposed in the (8k-3)th column and the plurality of second sub-pixels W disposed in the (8k-2)th column, and can be electrically connected to the plurality of first sub-pixels R disposed in the (8k-3)th column.

According to an embodiment of the present disclosure, the plurality of second sub-data lines SDL2-a and SDL2-b can be disposed adjacent to the plurality of second sub-pixels W and can be connected to the plurality of second sub-pixels W.

Specifically, the (2-a)th sub-data line SDL2-a can be disposed between the plurality of third sub-pixels G disposed in the (8k-5)th column and the plurality of second sub-pixels W disposed in the (8k-6)th column, and can be electrically connected to the plurality of second sub-pixels W disposed in the (8k-6)th column. In addition, the (2-b)th sub-data lines SDL2-b can be disposed between the plurality of third sub-pixels G disposed in the (8k-1)th column and the plurality of second sub-pixels W disposed in the (8k-2)th column, and can be electrically connected to the plurality of second sub-pixels W disposed in the (8k-2)th column.

According to an embodiment of the present disclosure, the plurality of third sub-data lines SDL3-a and SDL3-b can be disposed adjacent to the plurality of third sub-pixels G and can be connected to the plurality of third sub-pixels G.

Specifically, the (3-a)th sub-data line SDL3-a can be disposed between the plurality of third sub-pixels G disposed in the (8k-5)th column and the plurality of second sub-pixels W disposed in the (8k-6)th column, and can be electrically connected to the plurality of third sub-pixels G disposed in the (8k-5)th column. The (3-b)th sub-data line SDL3-b can be disposed between the plurality of third sub-pixels G disposed in the (8k-1)th column and the plurality of second sub-pixels W disposed in the (8k-2)th column, and can be electrically connected to the plurality of third sub-pixels G disposed in the (8k-1)th column.

According to an embodiment of the present disclosure, the plurality of fourth sub-data lines SDL4-a and SDL4-b can be disposed adjacent to the plurality of fourth sub-pixels B and can be connected to the plurality of fourth sub-pixels B.

Specifically, the (4-a)th sub-data line SDL4-a can be disposed between the plurality of third sub-pixels G disposed in the (8k-5)th column and the plurality of fourth sub-pixels B disposed in the (8k-4)th column, and can be electrically connected to the plurality of fourth sub-pixels B disposed in the (8k-4)th column. The (4-b)th sub-data lines SDL4-b can be disposed between the plurality of third sub-pixels G disposed in the (8k-1)th column and the plurality of fourth sub-pixels B disposed in the 8k-th column, and can be electrically connected to the plurality of fourth sub-pixels B disposed in the 8k-th column.

According to an embodiment of the present disclosure, a first data voltage DATA1 as a red data voltage can be applied to the first data line DL1, and a second data voltage DATA2 as a white data voltage can be applied to the second data line DL2. In addition, a third data voltage DATA3 as a green data voltage can be applied to the third data line DL3, and a fourth data voltage DATA4 as a blue data voltage can be applied to the fourth data line DL4.

Accordingly, the first data voltage DATA1 as a red data voltage can also be applied to the plurality of first sub-data lines SDL1-a and SDL1-b, and the second data voltage DATA2 as a white data voltage can also be applied to the plurality of second sub-data lines SDL2-a and SDL2-b. In addition, the third data voltage DATA3 as a green data voltage can also be applied to the plurality of third sub-data lines SDL3-a and SDL3-b, and the fourth data voltage DATA4 as a blue data voltage can also be applied to the plurality of fourth sub-data lines SDL4-a and SDL4-b.

According to an embodiment of the present disclosure, each of the plurality of gate lines GL1 to GL4 can be disposed on each of both opposing sides in the column direction of each of the first and second rows of the plurality of sub-pixels R, W, G, and B. The two gate lines GL2 and GL3 can be disposed between the first and second rows of the plurality of sub-pixels R, W, G, and B.

Specifically, referring to FIG. 19, the first gate line GL1 and the second gate line GL2 can be respectively disposed on both opposing sides in the column direction of the plurality of sub-pixels R, W, G, and B of the odd-numbered row, and the third gate line GL 3 and the fourth gate line GL 4 can be respectively disposed on both opposing sides in the column direction of the plurality of sub-pixels R, W, G, and B of the even-numbered row. Accordingly, the second gate line GL2 and the third gate line GL3 can be disposed between the plurality of sub-pixels R, W, G, and B of the odd-numbered row and the plurality of sub-pixels R, W, G, and B of the even-numbered row.

The plurality of pixels PX can be connected to the same gate line GL1 to GL4, and adjacent pixels PX among the plurality of pixels PX can be connected to different gate lines GL1 to GL4.

Specifically, referring to FIG. 19, the sub-pixel R disposed in the (8k-7)th column of the odd-numbered row odd, the sub-pixel G disposed in the (8k-5)th column of the odd-numbered row odd, the sub-pixel W disposed in the (8k-2)th column of the odd-numbered row odd, and the sub-pixel B disposed in the 8k-th column of the odd-numbered row odd are connected to the first gate line GL1. In addition, the sub-pixel W disposed in the (8k-6)th column of the odd-numbered row odd, the sub-pixel B disposed in the (8k-4)th column of the odd-numbered row odd, the sub-pixel R disposed in the (8k-3)th column of the odd-numbered row odd, and the sub-pixel G disposed in the (8k-1)th column of the odd-numbered row odd are connected to the second gate line GL2.

In addition, the sub-pixel R disposed in the (8k-7)th column of the even-numbered row even, the sub-pixel G disposed in the (8k-5)th column of the even-numbered row even, the sub-pixel W disposed in the (8k-2)th column of the even-numbered row even, and the sub-pixel B disposed in the 8k-th column of the even-numbered row even are connected to the third gate line GL3. In addition, the sub-pixel W disposed in the (8k-6)th column of the even-numbered row even, the sub-pixel B disposed in the (8k-4)th column of the even-numbered row even, the sub-pixel R disposed in the (8k-3)th column of the even-numbered row even, and the sub-pixel G disposed in the (8k-1)th column of the even-numbered row even are connected to the fourth gate line GL4.

Each of the sub-high potential voltage lines SVDDL1, SVDDL2, and SVDDL3 can be disposed between adjacent ones of the plurality of pixels PX.

Referring to FIG. 19, the display panel 110 operates in a Double Rate Driving (DRD) manner. In this regard, a driving and sensing ratio of each sub-pixel SP is 4:4 (i.e., 1:1), and the number of times of reference compensation is a total of two times in one scan line.

Hereinafter, a sensing sequence of sub-pixels when a pixel of a display panel according to an embodiment of the present disclosure has four sub-pixels will be described with reference to FIGS. 19 and 20

As shown in (a) of FIG. 20, when the gate voltage GATE1 at the turn-on level is applied via the first gate line GL1 while the data voltage is being supplied, the gate signal is transmitted to the first sub-pixel R 2011 disposed in the (8k-7)th column, the third sub-pixel G 2013 disposed in the (8k-5)th column, the second sub-pixel W 2016 disposed in the (8k-2)th column, and the fourth sub-pixel B 2018 disposed in the 8k-th column via the first gate line GL1. The first sub-pixel R 2011 disposed in the (8k-7)th column, the third sub-pixel G 2013 disposed in the (8k-5)th column, the second sub-pixel W 2016 disposed in the (8k-2)th column, and the fourth sub-pixel B 2018 disposed in the 8k-th column emit light.

Thereafter, as shown in (b) in FIG. 20, when the gate voltage GATE2 at the turn-on level is applied via the second gate line GL2, the gate signal is transmitted to the second sub-pixel W 2022 disposed in the (8k-6)th column, the fourth sub-pixel B 2024 disposed in the (8k-4)th column, the first sub-pixel R 2025 disposed in the (8k-3)th column, and the third sub-pixel G 2027 disposed in the (8k-1)th column via the second gate line GL2. The second sub-pixel W 2022 disposed in the (8k-6)th column, the fourth sub-pixel B 2024 disposed in the (8k-4)th column, the first sub-pixel R 2025 disposed in the (8k-3)th column, and the third sub-pixel G 2027 disposed in the (8k-1)th column emit light.

As described above, the four reference voltage lines RVL1, RVL2, RVL3, and RVL4 can be used to compensate for the sub-pixels R, W, G, and B of the two pixels PX.

Referring to FIG. 20, the driving and sensing ratio of each sub-pixel of the display panel 110 is 4:4 (i.e., 1:1), and the number of times of reference compensation in one scan line is a total of two times.

According to an embodiment of the present disclosure, the display device 100 can include a plurality of pixels in which each pixel includes four sub-pixels, and a plurality of reference voltage lines in which a reference voltage line is disposed every two sub-pixels of each of the plurality of pixels.

According to an embodiment of the present disclosure, two reference voltage lines can be disposed in each of the plurality of pixels.

According to an embodiment of the present disclosure, among the two reference voltage lines, a first reference voltage line can be disposed between a first sub-pixel and a second sub-pixel adjacent to the first sub-pixel of each pixel so as to supply a reference voltage to each of the first sub-pixel and the second sub-pixel.

According to an embodiment of the present disclosure, among the two reference voltage lines, a second reference voltage line can be disposed between a third sub-pixel adjacent to the second sub-pixel and a fourth sub-pixel adjacent to the third sub-pixel of each pixel so as to supply a reference voltage to each of the third sub-pixel and the fourth sub-pixel.

According to an embodiment of the present disclosure, the driving circuit can be disposed on the other of both opposing sides in the column direction of the light-emission area of each of the sub-pixels of each of the plurality of pixels and the display panel can operate in a single rate driving (SRD) driving manner.

According to an embodiment of the present disclosure, a high-potential voltage can be applied to the driving circuit of each of the four sub-pixels of each of the plurality of pixels via a high-potential voltage line. The high-potential voltage line can divide into three sub-high-potential voltage lines.

According to an embodiment of the present disclosure, among the three sub-high potential voltage lines, a first sub-high potential voltage line can be disposed on one side in the row direction of the first sub-pixel of the first pixel.

According to an embodiment of the present disclosure, among the three sub-high potential voltage lines, a second sub-high potential voltage line can be disposed between the first pixel and a second pixel adjacent to the first pixel.

According to an embodiment of the present disclosure, among the three sub-high potential voltage lines, a third sub-high potential voltage line can be disposed on the other side in the row direction of the second pixel.

According to an embodiment of the present disclosure, a driving circuit can be disposed on one of both opposing sides in the column direction of a light-emission area of each of the first sub-pixel and the third sub-pixel of the first pixel and the second sub-pixel and the fourth sub-pixel of the second pixel. A driving circuit can be disposed on the other of both opposing sides in the column direction of a light-emission area of each of the second sub-pixel and the fourth sub-pixel of the first pixel and the first sub-pixel and the third sub-pixel of the second pixel.

According to an embodiment of the present disclosure, the sub-pixels of the first pixel and the second pixel are alternately arranged with each other in the row direction in a manner flipped relative to each other in the column direction.

According to an embodiment of the present disclosure, the display device 100 can include a display panel including a plurality of pixels, a data driver configured to supply a data voltage to the display panel via a plurality of data lines, and a gate driver configured to supply a gate signal to the display panel via a plurality of gate lines, wherein the display panel can include a plurality of reference voltage lines arranged such that one reference voltage line is disposed every two sub-pixels of each of the plurality of pixels.

FIG. 21 is a timing diagram of a gate voltage, a data voltage, and a voltage charged into a storage capacitor according to an embodiment of the present disclosure according to FIG. 20.

Referring to FIG. 19, (a) in FIG. 20 and FIG. 21, when the first gate voltage GATE1 is the gate high voltage 2101, during the horizontal period, all of the switching transistors respectively connected to the plurality of first sub-pixels R disposed in the (8k-7)th column, the plurality of third sub-pixels G disposed in the (8k-5)th column, the plurality of second sub-pixels W disposed in the (8k-2)th column, and the plurality of fourth sub-pixels B disposed in the 8k-th column in the odd numbered row are turned on. In this case, the voltage V2 of the second node N2 of the driving transistor DT can be initialized with the reference voltage Vref for sensing operation. The second node N2 of the driving transistor DT can be in a floating state in which the reference voltage Vref is no longer applied to the storage capacitor SC, and in this floating state, the first sampling 1^{st} sampling is performed.

Referring to FIG. 19, (b) in FIG. 20 and FIG. 21, when the second gate voltage GATE2 is the gate high voltage 2111, during the horizontal period, all of the switching transistors respectively connected to the plurality of second sub-pixels W disposed in the (8k-6)th column, the plurality of fourth sub-pixels B disposed in the (8k-4)th column, the plurality of first sub-pixels R disposed in the (8k-3)th column and the plurality of third sub-pixels G disposed in the (8k-1)th column in the odd-numbered row are turned on. In this case, the voltage V2 of the second node N2 of the driving transistor DT can be initialized with the reference voltage Vref for sensing operation. The second node N2 of the driving transistor DT can be in a floating state in which the reference voltage Vref is no longer applied to the storage capacitor SC, and in this floating state, the second sampling 2^{nd} sampling is performed.

Referring to FIGS. 19 to 21, the driving ratio and the sensing ratio of the sub-pixel are equal to each other such that the sensing time taken for sensing the sub-pixels R, G, and B can be reduced.

The plurality of reference voltage lines RVL are added to the display panel 110 operating in the SRD driving manner, such that the driving ratio and the sensing ratio of the sub-pixel are equal to each other, thereby reducing the sensing time taken for sensing the sub-pixels R, W, G, and B.

Although some embodiments of the present disclosure have been described above with reference to the accompanying drawings, the present disclosure may not be limited to some embodiments and can be implemented in various different forms. Those of ordinary skill in the technical field to which the present disclosure belongs will be able to appreciate that the present disclosure can be implemented in other specific forms without changing the technical idea or essential features of the present disclosure. Therefore, it should be understood that some embodiments as described above are not restrictive but illustrative in all respects.

What is claimed is:

1. A display panel comprising:
a first pixel including a plurality of sub-pixels;
a second pixel disposed adjacent to the first pixel in a row direction and including a plurality of sub-pixels;
a plurality of data lines disposed so that each of the plurality of data lines applies a data voltage to sub-pixels configured to emit light of a same color being disposed in the first pixel and the second pixel, respectively; and
a plurality of reference voltage lines, wherein each of the plurality of reference voltage lines is disposed between two sub-pixels of the plurality of sub-pixels and applies a reference voltage to the two sub-pixels,
wherein each of the first pixel and the second pixel includes a first line-sub-pixel and a second line-sub-pixel adjacent to each other in the row direction, and
wherein for each pixel of the first pixel and the second pixel, the first line-sub-pixel and the second line-sub-pixel of each of the first pixel and the second pixel have structures flipped in a column direction relative to each other.

2. The display panel of claim 1, wherein each of the first pixel and the second pixel includes three sub-pixels or four sub-pixels.

3. The display panel of claim 1, wherein when each of the first pixel and the second pixel includes three sub-pixels, the plurality of reference voltage lines include three reference voltage lines disposed in a corresponding manner to a combination of the first pixel and the second pixel, or
wherein when each of the first pixel and the second pixel includes four sub-pixels, the plurality of reference voltage lines include four reference voltage lines disposed in a corresponding manner to a combination of the first pixel and the second pixel.

4. The display panel of claim 1, wherein one of the plurality of data lines is divided into a first sub-data line for applying a data voltage to the first line-sub-pixel of the first pixel and a second sub-data line for applying a data voltage to a sub-pixel of the second pixel, and
wherein the first line-sub-pixel of the first pixel and the sub-pixel of the second pixel are configured to emit light of a same color.

5. The display panel of claim 3, wherein each of the first pixel and the second pixel includes the three sub-pixels including a first sub-pixel, a second sub-pixel and a third sub-pixel sequentially arranged in the row direction,
wherein the three reference voltage lines include a first reference voltage line, a second reference voltage line and a third reference voltage line arranged in the row direction,
wherein the first reference voltage line is disposed between the first sub-pixel and the second sub-pixel of the first pixel so as to supply a reference voltage to each of the first sub-pixel and the second sub-pixel of the first pixel,
wherein the second reference voltage line is disposed between the second sub-pixel and the third sub-pixel of the second pixel so as to supply a reference voltage to each of the second sub-pixel and the third sub-pixel of the second pixel, and
wherein the third reference voltage line is disposed between the third sub-pixel of the first pixel and the first sub-pixel of the second pixel so as to supply a reference voltage to each of the third sub-pixel of the first pixel and the first sub-pixel of the second pixel.

6. The display panel of claim 3, wherein each of the first pixel and the second pixel includes the four sub-pixels including a first sub-pixel, a second sub-pixel, a third sub-pixel and a fourth sub-pixel sequentially arranged in the row direction,
wherein the four reference voltage lines include a first reference voltage line, a second reference voltage line, a third reference voltage line and a fourth reference voltage line arranged in the row direction,
wherein the first reference voltage line is disposed between the first sub-pixel and the second sub-pixel of the first pixel so as to supply a reference voltage to each of the first sub-pixel and the second sub-pixel of the first pixel,
wherein the second reference voltage line is disposed between the third sub-pixel and the fourth sub-pixel of the first pixel so as to supply a reference voltage to each of the third sub-pixel and the fourth sub-pixel of the first pixel,
wherein the third reference voltage line is disposed between the first sub-pixel and the second sub-pixel of the second pixel so as to supply a reference voltage to each of the first sub-pixel and the second sub-pixel of the second pixel, and
wherein the fourth reference voltage line is disposed between the third sub-pixel and the fourth sub-pixel of the second pixel so as to supply a reference voltage to each of the third sub-pixel and the fourth sub-pixel of the second pixel.

7. The display panel of claim 1, wherein each of the plurality of sub-pixels of each of the first pixel and the second pixel includes a light-emitting area and a driving circuit,
wherein the driving circuit of the first line-sub-pixel of each of the first pixel and the second pixels is disposed on one of opposing sides in the column direction of the light-emitting area of the first line-sub-pixel, and
wherein the driving circuit of the second line-sub-pixel of each of the first pixel and the second pixel is disposed on the other of opposing sides in the column direction of the light-emitting area of the second line-sub-pixel.

8. The display panel of claim 1, wherein each of the first pixel and the second pixel includes a first sub-pixel, a second sub-pixel and a third sub-pixel sequentially arranged in the row direction,
wherein each of the plurality of sub-pixels of each of the first pixel and the second pixel includes a light-emitting area and a driving circuit,
wherein for each sub-pixel of the first sub-pixel, the second sub-pixel and the third sub-pixel of the first pixel, the driving circuit of the sub-pixel is disposed on one of opposing sides in the column direction of the light-emitting area of the sub-pixel, and
wherein the driving circuit of the second sub-pixel of the first pixel is disposed on the other of opposing sides in the column direction of the light-emitting area of the second sub-pixel of the first pixel.

9. The display panel of claim 1, wherein each of the first pixel and the second pixel includes three sub-pixels including a first sub-pixel, a second sub-pixel and a third sub-pixel sequentially arranged in the row direction,
wherein each of the plurality of sub-pixels of each of the first pixel and the second pixel includes a light-emitting area and a driving circuit,
wherein for each sub-pixel of the first sub-pixel and the third sub-pixel of the second pixel, the driving circuit of the sub-pixel is disposed on the other of opposing sides in the column direction of the light-emitting area of the sub-pixel, and
wherein the driving circuit of the second sub-pixel of the second pixel is disposed on one of opposing sides in the column direction of the light-emitting area of the second sub-pixel of the second pixel.

10. The display panel of claim 1, wherein the display panel further comprises a plurality of gate lines configured to supply a gate signal to the first pixel and the second pixel,
wherein each of the first pixel and the second pixel includes three sub-pixels including a first sub-pixel, a second sub-pixel and a third sub-pixel sequentially arranged in the row direction,
wherein the plurality of gate lines include a first gate line and a second gate line arranged in the column direction and extending in the row direction, and
wherein the gate signal is applied to a driving circuit of each of the first sub-pixel of the first pixel, the third sub-pixel of the first pixel, and the second sub-pixel of the second pixel via the first gate line so that each of the first sub-pixel of the first pixel, the third sub-pixel of the first pixel, and the second sub-pixel of the second pixel operates.

11. The display panel of claim 10, wherein the gate signal is applied to a driving circuit of each of the second sub-pixel of the first pixel, the first sub-pixel of the second pixel, and the third sub-pixel of the second pixel via the second gate line so that each of the second sub-pixel of the first pixel, the first sub-pixel of the second pixel, and the third sub-pixel of the second pixel operates.

12. The display panel of claim 1, wherein each of the first pixel and the second pixel includes three sub-pixels including a first sub-pixel, a second sub-pixel and a third sub-pixel sequentially arranged in the row direction,
wherein each of the plurality of sub-pixels of each of the first pixel and the second pixel includes a light-emitting area and a driving circuit,
wherein for each sub-pixel of the first sub-pixel and the third sub-pixel of the first pixel, the driving circuit of the sub-pixel is disposed on the other of opposing sides in the column direction of the sub-pixel, and
wherein the driving circuit of the second sub-pixel of the first pixel is disposed on one of opposing sides in the column direction of the light-emitting area of the second sub-pixel of the first pixel.

13. The display panel of claim 1, wherein each of the first pixel and the second pixel includes three sub-pixels including a first sub-pixel, a second sub-pixel and a third sub-pixel sequentially arranged in the row direction,
wherein each of the plurality of sub-pixels of each of the first pixel and the second pixel includes a light-emitting area and a driving circuit,
wherein for each sub-pixel of the first sub-pixel and the third sub-pixel of the second pixel, the driving circuit of the sub-pixel is disposed on one of opposing sides in the column direction of the light-emitting area of the sub-pixel, and
wherein the driving circuit of the second sub-pixel of the second pixel is disposed on the other of opposing sides in the column direction of the light-emitting area of the second sub-pixel of the second pixel.

14. The display panel of claim 1, wherein the display panel further comprises a plurality of gate lines configured to supply a gate signal to the first pixel and the second pixel,
wherein each of the first pixel and the second pixels includes three sub-pixels including a first sub-pixel, a second sub-pixel and a third sub-pixel sequentially arranged in the row direction,
wherein the plurality of gate lines include a first gate line and a second gate line arranged in the column direction and extending in the row direction, and
wherein the gate signal is applied to a driving circuit of each of the second sub-pixel of the first pixel, the first sub-pixel of the second pixel, and the third sub-pixel of the second pixel via the first gate line so that each of the second sub-pixel of the first pixel, the first sub-pixel of the second pixel, and the third sub-pixel of the second pixel operate.

15. The display panel of claim 14, wherein the gate signal is applied to a driving circuit of each of the first sub-pixel of the first pixel, the third sub-pixel of the first pixel, and the second sub-pixel of the second pixel via the second gate line so that each of the first sub-pixel of the first pixel, the third sub-pixel of the first pixel, and the second sub-pixel of the second pixel operates.

16. The display panel of claim 1, wherein each of the first pixel and the second pixel includes three sub-pixels including a first sub-pixel, a second sub-pixel and a third sub-pixel sequentially arranged in the row direction,
wherein the display panel further comprises a high potential voltage line configured to apply a high potential voltage to a driving circuit of each of the plurality of sub-pixels of the first pixel and a driving circuit of each of the plurality of sub-pixels of the second pixel,
wherein the high potential voltage line is divided into three sub-high potential voltage lines including a first sub-high potential voltage line, a second sub-high potential voltage line and a third sub-high potential voltage line extending in the column direction and arranged in the row direction,
wherein the first sub-high potential voltage line is disposed on one side in the row direction of the first sub-pixel of the first pixel,
wherein the second sub-high potential voltage line is disposed between the second sub-pixel of the first pixel and the third sub-pixel of the first pixel, and
wherein the third sub-high potential voltage line is disposed between the first sub-pixel of the second pixel and the second sub-pixel of the second pixel.

17. The display panel of claim 1, wherein each of the first pixel and the second pixel includes four sub-pixels including a first sub-pixel, a second sub-pixel, a third sub-pixel and a fourth sub-pixel sequentially arranged in the row direction,
wherein the display panel further comprises a high potential voltage line configured to apply a high potential voltage to a driving circuit of each of the four sub-pixels of the first pixel and a driving circuit of each of the four sub-pixels of the second pixel,
wherein the high potential voltage line is divided into three sub-high potential voltage lines including a first sub-high potential voltage line, a second sub-high potential voltage line and a third sub-high potential voltage line extending in the column direction and arranged in the row direction,
wherein the first sub-high potential voltage line is disposed on one side in the row direction of the first sub-pixel of the first pixel,
wherein the second sub-high potential voltage line is disposed between the first pixel and the second pixel, and
wherein the third sub-high potential voltage line is disposed on another side in the row direction of the second pixel.

18. The display panel of claim 1, wherein each of the first pixel and the second pixel includes four sub-pixels including a first sub-pixel, a second sub-pixel, a third sub-pixel and a fourth sub-pixel sequentially arranged in the row direction,
wherein each of the plurality of sub-pixels of each of the first pixel and the second pixel includes a light-emitting area and a driving circuit,
wherein for each sub-pixel of the first sub-pixel and the third sub-pixel of the first pixel, the driving circuit of the sub-pixel is disposed on one of opposing sides in the column direction of the light-emitting area of the sub-pixel,
wherein for each sub-pixel of the second sub-pixel and the fourth sub-pixel of the first pixel, the driving circuit of the sub-pixel is disposed on the other of opposing sides in the column direction of the light-emitting area of the sub-pixel,
wherein for each sub-pixel of the second sub-pixel and the fourth sub-pixel of the second pixel, the driving circuit of the sub-pixel is disposed on one of opposing sides in the column direction of the light-emitting area of the sub-pixel,
wherein for each sub-pixel of the second sub-pixel and the fourth sub-pixel of the second pixel, the driving circuit of the sub-pixel is disposed on the other of opposing sides in the column direction of the light-emitting area of the sub-pixel, and
wherein the sub-pixels of the first pixel and the second pixel are alternately arranged with each other in the row direction in a manner flipped relative to each other in the column direction.

19. The display panel of claim 1, wherein each of the first pixel and the second pixels includes four sub-pixels including a first sub-pixel, a second sub-pixel, a third sub-pixel and a fourth sub-pixel sequentially arranged in the row direction,
wherein each of the plurality of sub-pixels of each of the first pixel and the second pixel includes a light-emitting area and a driving circuit,
wherein for each sub-pixel of the first sub-pixel and the second sub-pixels of the first pixel, the driving circuit of the sub-pixel is disposed on one of opposing sides in the column direction of the light-emitting area of the sub-pixel,
wherein for each sub-pixel of the third sub-pixel and the fourth sub-pixels of the first pixel, the driving circuit of the sub-pixel is disposed on the other of opposing sides in the column direction of the light-emitting area of the sub-pixel,
wherein for each sub-pixel of the third sub-pixel and the fourth sub-pixels of the second pixel, the driving circuit of the sub-pixel is disposed on one of opposing sides in the column direction of the light-emitting area of the sub-pixel,
wherein for each sub-pixel of the first sub-pixel and the second sub-pixels of the second pixel, the driving circuit of the sub-pixel is disposed on the other of opposing sides in the column direction of the light-emitting area of the sub-pixel, and
wherein the sub-pixels of the first pixel and the second pixel are alternately arranged with each other in the row direction in a manner flipped relative to each other in the column direction.

20. A display panel comprising:
a first pixel including a plurality of sub-pixels;
a second pixel disposed adjacent to the first pixel in a row direction and including a plurality of sub-pixels;
a plurality of data lines disposed such that each of the plurality of data lines applies a data voltage to a sub-pixel in the first pixel and a sub-pixel in the second pixel emitting light of the same color as the sub-pixel in the first pixel; and
a plurality of reference voltage lines, wherein each of the plurality of reference voltage lines is disposed between two sub-pixels of the plurality of sub-pixels in the first pixel and the plurality of sub-pixels in the second pixel and applies a reference voltage to the two sub-pixels,
wherein the first pixel and the second pixel have structures flipped in a column direction relative to each other.

21. The display panel of claim 20,
wherein the sub-pixels of the first pixel and the sub-pixels of the second pixel have structures flipped in a column direction relative to each other.

22. A display panel, including:
a first reference voltage line for supplying a reference voltage to at least one sub-pixel of a first pixel,
a second reference voltage line for supplying a reference voltage to at least one sub-pixel of a second pixel disposed at a position adjacent to the first pixel, and
a third reference voltage line disposed between the first pixel and the second pixel.
